(19) United States
(12) Patent Application Publication
(10) Pub. No.: US 2024/0258767 A1
(43) Pub. Date: Aug. 1, 2024

(54) LASER ELEMENT AND ELECTRONIC DEVICE

(71) Applicant: SONY GROUP CORPORATION, TOKYO (JP)

(72) Inventors: GEN YONEZAWA, TOKYO (JP); TOSHIYA TAKAGISHI, TOKYO (JP); MISAKI SHIMIZU, TOKYO (JP)

(21) Appl. No.: 18/559,511

(22) PCT Filed: May 26, 2021
(86) PCT No.: PCT/JP2021/020077

§ 371 Date: Nov. 7, 2023

(51) Int. Cl. H01S 5/024; H01S 3/0941; H01S 3/10; H01S 3/113; H01S 3/16; H01S 5/02345; H01S 5/183; H01S 5/343

(52) U.S. Cl. CPC H01S 5/02484; H01S 3/09415; H01S 3/10061; H01S 3/113; H01S 3/1618; H01S 3/1643; H01S 5/02345; H01S 5/02407; H01S 5/18305; H01S 5/34313

(57) ABSTRACT

To prevent a decrease in oscillation efficiency of laser light and a decrease in conversion efficiency of an optical wavelength due to thermal interference. A laser element includes: a laminated semiconductor layer including a first reflection layer with respect to a first wavelength and an active layer that performs surface emission at the first wavelength; a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface on a side opposite to the first surface; a fourth reflection layer with respect to the second wavelength disposed on the second surface or disposed on a rear side of the optical axis with respect to the second surface; a first resonator that causes light of the first wavelength to resonate between the first reflection layer and the third reflection layer; a second resonator that causes light of the second wavelength to resonate between the second reflection layer and the fourth reflection layer; and a heat exhaust unit that is disposed between the laminated semiconductor layer and the laser medium and exhausts heat generated in at least one of the laminated semiconductor layer or the laser medium.

### TECHNICAL FIELD

The present disclosure relates to a laser element and an electronic device.

### BACKGROUND ART

The peak power of a laser is defined as the pulse energy divided by the pulse width, and in order to achieve higher peak power, it is important to obtain a shorter pulse width. A Q-switched solid-state laser that outputs a laser pulse has a feature that the length of its own resonator is proportional to the obtained pulse width, and the minimum resonator length is determined by the length of the used solid-state laser medium. The length of the solid-state laser medium installed in the resonator as a gain medium is determined by the amount of excitation light absorbed. Thus, when the length of the solid-state laser medium is simply reduced, the excitation light cannot be sufficiently absorbed, leading to a significant decrease in excitation efficiency.

Therefore, in the conventional method of externally exciting a Q-switched solid-state laser medium with a semiconductor laser, it is not preferable to make the length of the solid-state laser medium shorter than the absorption length of excitation light, and a shorter pulse cannot be obtained. That is, reducing the length of the solid-state laser medium in order to obtain a short pulse width leads to a decrease in the amount of excitation light absorbed and a decrease in excitation efficiency. In contrast, increasing the length of the solid-state laser medium in order to increase the amount of excitation light absorbed leads to a longer resonator length and an extended pulse width, and hence such a trade-off exists in the conventional method.

Meanwhile, in terms of manufacturing and the stability of light source output, the conventional Q-switched solid-state laser requires assembly adjustment by high-precision positioning of a plurality of optical elements, thus reducing mass productivity and making cost reduction difficult, and also posing challenges in the stability light source output due to positional displacement of each optical element.

Conventionally, for example, there is known a method of generating a short-pulse laser by externally exciting a Q-switched solid-state laser using a semiconductor laser (cf. Patent Documents 1 and 2). Since the obtained pulse width is proportional to the resonator length of the Q-switched solid-state laser, it is desirable to reduce the resonator length to obtain a shorter pulse width in order to obtain higher laser peak power.

However, in the conventional method, the thickness of the solid-state laser medium that can be used is limited by the absorption length determined by the wavelength of a semiconductor laser for excitation and the absorption coefficient of the solid-state laser medium at the wavelength. For example, in the case of Nd:YAG (10at %) that is generally most often used in a Q-switched solid-state laser, the absorption length for excitation light having a wavelength of 808 nm is about 10 mm. When the length of the solid-state laser medium is made shorter than this length, the remaining excitation light that has not been absorbed returns to the semiconductor laser side to make the operation unstable or cause heat generation. For disk lasers, a method of folding back excitation light several times has also been proposed, but the method requires a complicated excitation optical system and poses challenges in size reduction and low cost.

Furthermore, conventionally, in order to reduce the size of a laser light source, for example, as disclosed in Patent Document 3, a method of integrally laminating a surface-emitting laser (vertical cavity surface-emitting laser (VCSEL)) for excitation and a solid-state laser medium has been proposed. However, there is only a description of “integrally laminating”, and no specific description of whether light transmission surfaces are bonded to each other, which bonding process is used, and how to solve problems caused by the process.

### CITATION LIST

### Patent Document

Patent Document 1: Japanese Patent Application Laid-Open No. 2013-219232
Patent Document 2: Japanese Patent Application Laid-Open No. 2019-176119
Patent Document 3: Japanese Patent Application Laid-Open No. 2007-173393

### SUMMARY OF THE INVENTION

### Problems to be Solved by the Invention

When the surface-emitting laser and the solid-state laser medium are integrated and reduced in size, thermal interference may occur between the surface-emitting laser and the solid-state laser medium. The occurrence of thermal interference causes a decrease in the oscillation efficiency of the laser light in the surface-emitting laser a decrease in the conversion efficiency of the optical wavelength in the solid-state laser medium.

Therefore, the present disclosure provides a laser element and an electronic device capable of preventing a decrease in oscillation efficiency of laser light due to thermal interference and a decrease in conversion efficiency of an optical wavelength.

### Solutions to Problems

In order to solve the problem described above, according to the present disclosure, there is provided a laser element including:
a laminated semiconductor layer including a first reflection layer with respect to a first wavelength and an active layer that performs surface emission at the first wavelength;
a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface on a side opposite to the first surface;
a fourth reflection layer with respect to the second wavelength, the forth reflection layer being disposed on the second surface or disposed on a rear side of the optical axis with respect to the second surface;
a first resonator that causes light of the first wavelength to resonate between the first reflection layer and the third reflection layer;
a second resonator that causes light of the second wavelength to resonate between the second reflection layer and the fourth reflection layer; and
a heat exhaust unit that is disposed between the laminated semiconductor layer and the laser medium, and exhausts heat generated in at least one of the laminated semiconductor layer or the laser medium,
in which the optical axis of the laminated semiconductor layer and an optical axis of the laser medium are coaxially arranged.

The heat exhaust unit may include a first member disposed between the laminated semiconductor layer and the laser medium and having a thermal conductivity higher than the laser medium.

The laser element may further include a metal layer disposed on a part or all of a surface of the first member on a side facing the laser medium and having a thermal conductivity higher than the laminated semiconductor layer and the laser medium.

The laser element may further include a second member that is bonded to a side surface of the laminated semiconductor layer, a side surface of the first member, and a side surface of the laser medium and dissipates heat transmitted to the first member.

The laser element may further include:
a substrate that supports the laminated semiconductor layer; and
bonding wire connected to a pad on the substrate and an electrode of the laminated semiconductor layer,
in which the second member may be disposed to cover the side surface of the laminated semiconductor layer, the side surface of the laser medium, and the bonding wire.

The first member may contain at least one of sapphire or diamond, and the second member may include a metal material.

The laser element may further include a protective layer that is disposed on a surface of the first member on a side facing the laminated semiconductor layer, transmits light of the first wavelength, and reflects light of the second wavelength.

The first member may include a first region that transmits the light of the first wavelength, and a second region that is disposed around the first region and has a higher thermal conductivity than the laser medium.

The second region may be an insulating material or a metal material.

The second region may be disposed to surround the first region, and
an outer peripheral surface of the second region or a corner portion of the outer peripheral surface may be located at an equal distance from a center position of the first region.

The laser element may further include a plurality of the first resonators and a plurality of the second resonators in a plane direction of the laminated semiconductor layer, the heat exhaust unit, and the laser medium.

The heat exhaust unit may have an air gap disposed between the laminated semiconductor layer and the laser medium.

The laser element may further include a first optical element that is disposed between the second reflection layer and the fourth reflection layer, and increases a beam diameter of the light of the second wavelength.

The first resonator may include a second optical element that condenses the light of the first wavelength in an optical axis direction.

The laser element may further include a saturable absorber including a fourth reflection layer on a third surface on a side opposite to the laser medium,
in which the optical axis of the laminated semiconductor layer, the optical axis of the laser medium, and the optical axis of the saturable absorber may be coaxially arranged.

The laminated semiconductor layer, the laser medium, and the saturable absorber may be integrally bonded.

The laser element may further include a polarization control element that is disposed between the laser medium and the saturable absorber or on a rear side of an optical axis with respect to the saturable absorber, and controls a polarization state of the light of the second wavelength.

The fourth reflection layer may be an output coupling mirror in the second resonator.

The laminated semiconductor layer may include a fifth reflection layer with respect to the first wavelength disposed on a side closer to the laser medium than the first reflection layer, and
the fifth reflection layer may transmit a part of the light of the first wavelength.

According to the present disclosure, there is provided an electronic device including:
a laser element; and
a control unit that performs control to emit light from the laser element,
in which
the laser element includes
a laminated semiconductor layer including a first reflection layer with respect to a first wavelength and an active layer that performs surface emission at the first wavelength,
a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface on a side opposite to the first surface,
a fourth reflection layer with respect to the second wavelength, the forth reflection layer being disposed on the second surface or disposed on a rear side of the optical axis with respect to the second surface,
a first resonator that causes light of the first wavelength to resonate between the first reflection layer and the third reflection layer,
a second resonator that causes light of the second wavelength to resonate between the second reflection layer and the fourth reflection layer, and
a heat exhaust unit that is disposed between the laminated semiconductor layer and the laser medium, and exhausts heat generated in at least one of the laminated semiconductor layer or the laser medium, and
in which the optical axis of the laminated semiconductor layer and an optical axis of the laser medium are coaxially arranged.

### BRIEF DESCRIPTION OF DRAWINGS

FIG. 1 is a diagram illustrating a basic configuration of a laser element according to the present disclosure.

FIG. 2 is a schematic cross-sectional view of a laser element including a heat exhaust unit according to a first mode.

FIG. 3 is a schematic cross-sectional view of a laser element including a heat exhaust unit according to a second mode.

FIG. 4 is a schematic cross-sectional view of a laser element including a heat exhaust unit according to a third mode.

FIG. 5 is a schematic cross-sectional view of a laser element including a heat exhaust unit according to a fourth mode.

FIG. 6 is a schematic cross-sectional view of a laser element including a heat exhaust unit according to a fifth mode.

FIG. 7 is a schematic cross-sectional view of a laser element including a heat exhaust unit according to a sixth mode.

FIG. 8 is a schematic cross-sectional view of a laser element including a heat exhaust unit according to a seventh mode.

FIG. 9 is a schematic cross-sectional view of a laser element including a heat exhaust unit according to an eighth mode.

FIG. 10 is a schematic cross-sectional view of a laser element including a heat exhaust unit according to a ninth mode.

FIG. 11A is a view schematically illustrating an example of a planar shape of a heat exhaust unit according to a tenth mode.

FIG. 11B is a view schematically illustrating another example of the planar shape of the heat exhaust unit according to the tenth mode.

FIG. 11C is a view schematically illustrating another example of the planar shape of the heat exhaust unit according to the tenth mode.

FIG. 11D is a view schematically illustrating another example of the planar shape of the heat exhaust unit according to the tenth mode.

FIG. 12 is a schematic cross-sectional view of a laser array in which a plurality of lens elements is arranged in a one-dimensional direction or a two-dimensional direction.

FIG. 13A is a diagram illustrating a temperature distribution of a laser light source at a center portion of a laser array not including the heat exhaust unit.

FIG. 13B is a diagram illustrating a temperature distribution of a laser light source at a center portion of a laser array including the heat exhaust unit.

FIG. 13C is a diagram illustrating a temperature distribution of the laser light source at the corner portion of the laser array not including the heat exhaust unit.

FIG. 13D is a diagram illustrating a temperature distribution of the laser light source at the corner portion of the laser array including the heat exhaust unit.

FIG. 14 is a diagram schematically illustrating a manufacturing process of the laser element of the present disclosure.

FIG. 15 is a diagram illustrating a laser element in which a first transparent medium is disposed between an excitation light source and a solid-state laser medium.

FIG. 16 is a diagram illustrating a basic configuration of a laser element not including a saturable absorber.

FIG. 17A is a perspective view illustrating a configuration of Innoslab.

FIG. 17B is a plan view as viewed from the Y direction in FIG. 17A.

FIG. 17C is a plan view as viewed from the Z direction in FIG. 17A.

FIG. 18A is a cross-sectional view of a laser amplification element according to the present disclosure.

FIG. 18B is a perspective view of the laser amplification element according to the present disclosure.

FIG. 18C is a plan view schematically illustrating an optical path of laser light in the laser amplification element.

FIG. 19A is a cross-sectional view of the laser amplification element in which the heat exhaust performance of a first heat exhaust member in FIG. 18A has been improved.

FIG. 19B is a transverse cross-sectional view taken along line A-A in FIG. 19A.

FIG. 20 is a diagram illustrating an example of a schematic configuration of an endoscope system.

FIG. 21 is a block diagram illustrating an example of a functional configuration of a camera and a camera control unit (CCU) illustrated in FIG. 20.

FIG. 22 is a diagram illustrating an example of a schematic configuration of a microscopic surgery system.

### MODE FOR CARRYING OUT THE INVENTION

Hereinafter, an embodiment of a laser element will be described with reference to the drawings. Although the principal components of the laser element will be mainly described hereinafter, the laser element may include components and have functions that are not illustrated or described. The following description does not exclude configuration parts and functions that are not illustrated or described.

### (Technical Features of Laser Element According to Present Disclosure)

First, technical features of a laser element according to the present disclosure will be described before descriptions of an internal configuration and an operation of the laser element according to the present disclosure.

A laser element according to the present disclosure has a configuration in which a structure using a part of a surface-emitting laser as an excitation light source and a solid-state laser medium for Q-switching are integrally bonded. Note that, as described later, the laser element according to the present disclosure may include a laser element not having a Q-switching function, but a laser element having the Q-switching function will be first described.

In the laser element according to the present disclosure, the solid-state laser medium for Q-switching is shared by two resonators. These two resonators include a first resonator that resonates at a first wavelength and a second resonator (also referred to as a Q-switched solid-state laser resonator) that resonates at a second wavelength.

Since the two resonators share the solid-state laser medium, high-intensity excitation of the solid-state laser medium can be performed in the first resonator even when the solid-state laser medium is reduced, and a laser pulse having a shorter pulse width can be generated.

Furthermore, the laser element according to the present disclosure is an integrated laminated structure that can be fabricated by using a semiconductor process technology, and is thus excellent in mass productivity as well as laser output stability.

Here, the excitation light source is a form of a surface-emitting laser (vertical cavity surface-emitting laser (VCSEL)). This is different from the VCSEL in that at least one of mirrors forming the resonator is provided outside a laminated semiconductor layer, which is a main body of the excitation light source. As described later, the laser element according to the present disclosure has a structure in which the solid-state laser medium is disposed between the laminated semiconductor layer and the mirror disposed outside the laminated semiconductor layer.

As described above, the laser element according to the present disclosure can generate a laser pulse having a short pulse width by Q-switching, but heat generated due to non-conversion of light by the excitation light source may be transferred to the solid-state laser medium, and the temperature of the solid-state laser medium may rise. When the temperature of the solid-state laser medium rises, the conversion efficiency of the optical wavelength from the first wavelength to the second wavelength in the solid-state laser medium decreases. The higher the light output intensity of the excitation light source, the greater the influence of a decrease in conversion efficiency of the optical wavelength in the solid-state laser medium.

Furthermore, in addition to the heat generated by the excitation light source, the heat generated by the solid-state laser medium may be transferred to the excitation light source, and the temperature of the excitation light source may further rise. When the temperature of the excitation light source rises, the I-L characteristic (light emission efficiency) of the excitation light source deteriorates. Moreover, when the temperature of the excitation light source rises, the temperature (junction temperature Tj) of the active layer of the excitation light source rises, and long-term reliability (mean time to failure (MTTF)) deteriorates.

In order to solve the problems described above, a laser element according to the present disclosure has the following three features.

(1) The first resonator and the second resonator share the solid-state laser medium. The first resonator includes the excitation light source and the solid-state laser medium. The second resonator includes the solid-state laser medium and a saturable absorber, and performs Q-switched laser oscillation using excitation light from the first resonator.

(2) A heat exhaust unit is provided between the excitation light source and the solid-state laser medium. The heat exhaust unit exhausts heat generated by at least one of the excitation light source or the solid-state laser medium.

(3) The excitation light source, the solid-state laser medium, and the saturable absorber have an integrated structure.

In the laser element according to the present disclosure, the solid-state laser medium in the first resonator absorbs the excitation light generated by injecting a current into the excitation light source. The solid-state laser medium forms the second resonator together with the saturable absorber installed adjacent to the first resonator. When the solid-state laser medium comes into a sufficiently excited state, and an output of spontaneous emission light increases above a certain threshold, a light absorption rate in the saturable absorber rapidly decreases, and the spontaneous emission light generated in the solid-state laser medium can be transmitted through the saturable absorber, causing induced emission in the solid-state laser medium. This results in Q-switched pulse oscillation.

### (Basic Configuration of Laser Element)

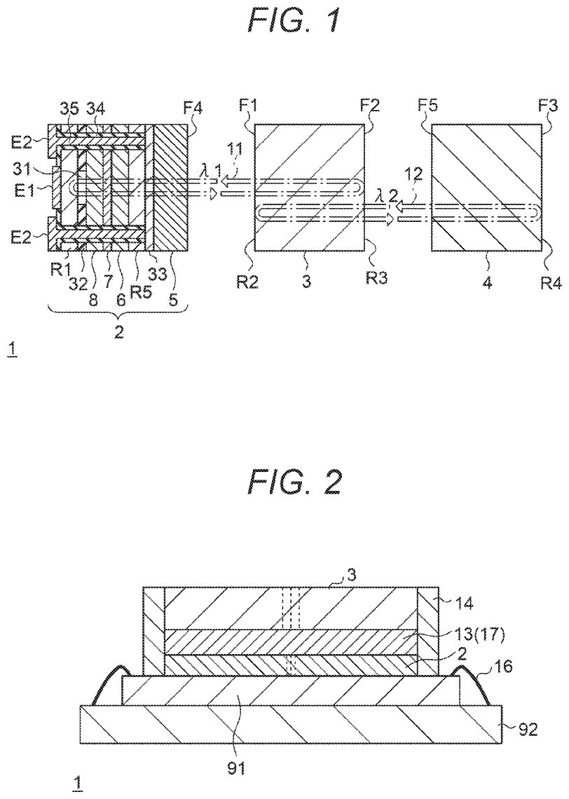

A specific embodiment of the laser element according to the present disclosure will be described below. FIG. 1 is a diagram illustrating a basic configuration of a laser element 1 according to the present disclosure. The laser element 1 of FIG. 1 has a configuration in which an excitation light source 2, a solid-state laser medium 3, and a saturable absorber 4 are integrally bonded.

The excitation light source 2 is a partial structure of VCSEL described above and includes the laminated semiconductor layer having a laminated structure. Hereinafter, the excitation light source 2 is sometimes referred to as a laminated semiconductor layer 2. The excitation light source 2 in FIG. 1 has a structure obtained by laminating a substrate 5, an n-contact layer 33, a fifth reflection layer R5, a cladding layer 6, an active layer 7, a cladding layer 8, a pre-oxidation layer 31, and a first reflection layer R1 in this order. Note that the laser element 1 of FIG. 1 has a bottom emission type configuration in which continuous wave (CW) excitation light is emitted from the substrate 5, but may have a top emission type configuration in which the CW excitation light is emitted from the first reflection layer R1 side.

The substrate 5 is, for example, an n-GaAs substrate 5. The n-GaAs substrate 5 absorbs light of a first wavelength Δ1, which is the excitation wavelength of the excitation light source 2, at a certain rate, and hence is desirable to make the n-GaAs substrate 5 as thin as possible. In contrast, it is desirable to provide such a degree of thickness that can maintain mechanical strength at the time of a bonding process to be described later.

The active layer 7 performs surface emission at the first wavelength λ1. The cladding layers 6, 8 are, for example, AlGaAs cladding layers. The first reflection layer R1 reflects the light of the first wavelength λ1. The fifth reflection layer R5 has a certain transmittance with respect to the light of the first wavelength λ1. For the first reflection layer R1 and the fifth reflection layer R5, for example, a semiconductor distributed Bragg reflector (DBR) capable of performing electrical conduction is used. A current is externally injected via the first reflection layer R1 and the fifth reflection layer R5, recombination and light emission occur in a quantum well in the active layer 7, and laser oscillation at the first wavelength λ1 is performed. A part of the pre-oxidation layer (e.g., AlAs layer) 31 on the cladding layer side of the first reflection layer R1 is oxidized to become a post-oxidation layer (e.g., Al₂O₃ layer) 32.

The fifth reflection layer R5 is disposed on, for example, the n-GaAs substrate 5. For example, the fifth reflection layer R5 includes a multilayer reflection film containing Al_{z1}Ga_{1-z1}As/Al_{z2}Ga_{1-z2}As (0≤z1≤z2≤1) to which an n-type dopant (e.g., silicon) is added. The fifth reflection layer R5 is also referred to as an n-DBR. More specifically, the n-contact layer 33 is disposed between the fifth reflection layer R5 and the n-GaAs substrate 5.

The active layer 7 includes, for example, a multiple quantum well layer in which an Alₓ₁In_{y1}Ga_{1-x1-y1}As layer and an Alₓ₃In_{y3}Ga_{1-x3-y3}As layer are laminated.

The first reflection layer R1 includes, for example, a multilayer reflection film containing Alz3Ga1−z3As/Alz4Ga1−z4As (0≤z3≤z4≤1) to which a p-type dopant (e.g., carbon) is added. The first reflection layer R1 is also referred to as a p-DBR.

Each of the semiconductor layers R5, 6, 7, 8, R1 in the excitation light source 2 can be formed by using a crystal growth method such as a metal-organic chemical vapor deposition (MOCVD) method or a molecular beam epitaxy (MBE) method. Then, after the crystal growth, driving by current injection becomes possible after processes such as mesa etching for element separation, formation of an insulating film, and vapor deposition of an electrode film.

The solid-state laser medium 3 is bonded to the end face on the side opposite to the fifth reflection layer R5 of the n-GaAs substrate 5 of the excitation light source 2. Hereinafter, the end face on the excitation light source 2 side of the solid-state laser medium 3 is referred to as a first surface F1, and the end face on the saturable absorber 4 side of the solid-state laser medium 3 is referred to as a second surface F2. Furthermore, a laser pulse emission surface of the saturable absorber 4 is referred to as a third surface F3, and the end face on the solid-state laser medium 3 side of the excitation light source 2 is referred to as a fourth surface F4. Furthermore, the end face on the solid-state laser medium 3 side of the saturable absorber 4 is referred to as a fifth surface F5. Although illustrated separately for convenience in FIG. 1, the fourth surface F4 of the excitation light source 2 is bonded to the first surface F1 of the solid-state laser medium 3, and the second surface F2 of the solid-state laser medium 3 is bonded to the fifth surface F5 of the saturable absorber 4.

The laser element 1 of FIG. 1 includes a first resonator 11 and a second resonator 12. The first resonator 11 causes the light of the first wavelength λ1 to resonate between the first reflection layer R1 in the excitation light source 2 and a third reflection layer R3 in the solid-state laser medium 3. The second resonator 12 causes light of a second wavelength λ2 to resonate between a second reflection layer R2 in the solid-state laser medium 3 and a fourth reflection layer R4 in the saturable absorber 4.

The second resonator 12 is also referred to as a Q-switched solid-state laser resonator 12. A third reflection layer R3, which is a high reflection layer, is provided in the solid-state laser medium 3 so that the first resonator 11 can perform a stable resonance operation. In the normal excitation light source 2, a partially reflecting mirror for emitting the light of the first wavelength λ1 to the outside is disposed at a position of the third reflection layer R3 in FIG. 1. In contrast, in the laser element 1 of FIG. 1, the high reflection layer is used as the third reflection layer R3 in order to use the third reflection layer R3 for confining power of the excitation light of the first wavelength λ1 in the first resonator 11.

In this manner, three reflection layers (first reflection layer R1, fifth reflection layer R5, and third reflection layer R3) are provided inside the first resonator 11 including the excitation light source 2 and the solid-state laser medium 3. Therefore, the first resonator 11 has a coupled resonator (coupled cavity) structure.

The solid-state laser medium 3 is excited by confining the power of the excitation light of the first wavelength λ1 in the first resonator 11. Therefore, Q-switched laser pulse oscillation occurs in the second resonator 12. The second resonator 12 causes light of a second wavelength λ2 to resonate between a second reflection layer R2 in the solid-state laser medium 3 and a fourth reflection layer R4 in the saturable absorber 4. The second reflection layer R2 is a high reflection layer, whereas the fourth reflection layer R4 is a partial reflection layer. In FIG. 1, the fourth reflection layer R4 is provided on the end face of the saturable absorber 4, but the fourth reflection layer R4 may be disposed on the rear side of the optical axis with respect to the saturable absorber 4. The rear side of the optical axis is in a light emission direction on the optical axis. That is, the fourth reflection layer R4 is not necessarily provided inside or on the surface of the saturable absorber 4. The fourth reflection layer R4 is an output coupling mirror in the second resonator 12.

The solid-state laser medium 3 contains, for example, ytterbium (Yb)-doped yttrium aluminum garnet (YAG) crystal Yb:YAG. In this case, the first wavelength λ1 of the first resonator 11 is 940 nm, and the second wavelength λ2 of the second resonator 12 is 1030 nm.

The solid-state laser medium 3 is not limited to Yb:YAG, and for example, at least any material of Nd:YAG, Nd:YVO4, Nd:YLF, Nd:glass, Yb:YAG, Yb:YLF, Yb:FAP, Yb:SFAP, Yb:YVO, Yb:glass, Yb:KYW, Yb:BCBF, Yb:YCOB, Yb:GdCOB, and YB:YAB can be used as the solid-state laser medium 3. The form is not limited to crystal, and the use of a ceramic material is not prevented.

Furthermore, the solid-state laser medium 3 may be a four-level system solid-state laser medium 3 or a quasi-three-level system solid-state laser medium 3. However, since an appropriate excitation wavelength (first wavelength λ1) varies depending on each crystal, it is necessary to select the semiconductor material of the active layer 7 in the excitation light source 2 according to the material of the solid-state laser medium 3.

The saturable absorber 4 contains, for example, a chromium (Cr)-doped YAG (Cr:YAG) crystal. The saturable absorber 4 is a material in which the transmittance increases when the intensity of incident light exceeds a predetermined threshold. The excitation light of the first wavelength λ1 by the first resonator 11 increases the transmittance of the saturable absorber 4 to emit the laser pulse of the second wavelength λ2. This is referred to as a Q-switch. As the material of the saturable absorber 4, V:YAG can also be used. However, other types of saturable absorber 4 may also be used. Furthermore, the use of an active Q-switched element as the Q-switch is not prevented.

In FIG. 1, the excitation light source 2, the solid-state laser medium 3, and the saturable absorber 4 are separately illustrated, but they are bonded to be integrated by using a bonding process to form a laminated structure. Examples of the bonding process include surface activation bonding, atomic diffusion bonding, plasma activation bonding, and the like. Alternatively, other bonding (adhering) processes can be used.

To stably bond the solid-state laser medium 3 to the excitation light source 2, it is necessary to flatten the surface of the n-GaAs substrate 5 in the excitation light source 2. Therefore, as described above, it is desirable that electrodes E1, E2 for injecting a current into the first reflection layer R1 and the fifth reflection layer R5 be arranged so as not to be exposed at least on the surface of the n-GaAs substrate 5. In the example in FIG. 1, the electrodes E1, E2 are arranged on the end face on the first reflection layer R1 side of the excitation light source 2. The electrode E1 is a p-electrode, and is electrically conducted with the first reflection layer R1. The electrode E2 is an n-electrode, and is formed by filling an inner wall of a trench reaching the n-contact layer 33 from the first reflection layer R1 with a conductive material 35 via an insulating film 34. Arranging the electrodes E1, E2 on the same end face of the excitation light source 2 as in FIG. 1 enables this end face to be soldered to a support substrate (not illustrated). Also, when a plurality of laser elements is arranged in an array, arranging the electrodes E1, E2 on the same end face enables this end face to be mounted on the support substrate. Note that the shapes and arranged positions of the electrodes E1, E2 illustrated in FIG. 1 are illustrative only.

In this manner, forming the laser element 1 of FIG. 1 into a laminated structure facilitates formation of a plurality of chips by dicing the laminated structure to separate after fabricating the same, or formation of a laser array in which a plurality of laser elements 1 is arranged in an array on one substrate.

In a case where the laser element 1 having the laminated structure is fabricated by the bonding process, arithmetic average roughness Ra of each surface layer needs to be about 1 nm or less, and is desirably 0.5 nm or less. Chemical mechanical polishing (CMP) is used to implement the surface layer having such arithmetic average roughness. Furthermore, in order to avoid an optical loss at the interface of each layer, a dielectric multilayer film may be disposed between the layers, and the layers may be bonded via the dielectric multilayer film. For example, the GaAs substrate 5 as the base substrate of the excitation light source 2 has a refractive index n of 3.2 with respect to a wavelength of 940 nm, which is higher than that of YAG (n:1.7) or a general dielectric multilayer film material. Therefore, when the solid-state laser medium 3 and the saturable absorber 4 are bonded to the excitation light source 2, it is necessary to prevent optical loss due to refractive index mismatch from occurring. Specifically, it is desirable to dispose an anti-reflection film (AR coating film or non-reflection coating film) that does not reflect the light of the first wavelength λ1 of the first resonator 11 between the excitation light source 2 and the solid-state laser medium 3. Furthermore, it is desirable to arrange an anti-reflection film (AR coating film or non-reflection coating film) also between the solid-state laser medium 3 and the saturable absorber 4.

Polishing is sometimes difficult depending on a bonding material, and for example, a material that is transparent with respect to the first wavelength λ1 and the second wavelength λ2, such as SiO₂, may be deposited as a base layer for bonding, and this SiO₂ layer may be polished to have arithmetic average roughness Ra of about 1 nm (preferably 0.5 nm or less) and used as an interface for bonding. Here, a material other than SiO₂ can be used as the base layer, and the material is not limited. Note that a non-reflection film may be provided between SiO₂ as the material of the base layer and a base material layer.

Examples of the dielectric multilayer film include a short-wave pass filter (SWPF), a long-wave pass filter (LWPF), a band pass filter (BPF), an anti-reflection (AR) protective film, and the like, and the dielectric multilayer film is a coating layer formed by alternately layering a high refractive material layer and a low refractive material layer. It is desirable to arrange different types of dielectric multilayer films as necessary. A physical vapor deposition (PVD) method can be used as a film deposition method for the dielectric multilayer film, and specifically, a film deposition method such as vacuum vapor deposition, ion-assisted vapor deposition, and sputtering can be used. Which film deposition method is applied is not limited. Furthermore, any characteristic of the dielectric multilayer film can be selected, and for example, the second reflection layer R2 may be a short-wave pass filter, and the third reflection layer R3 may be a long-wave pass filter. Furthermore, applying the long-wave pass filter to the third reflection layer R3 makes it possible to prevent the first wavelength from entering the saturable absorber and to prevent malfunction of the Q-switch. Note that the short-wave pass means that the light of the first wavelength λ1 is transmitted and the light of the second wavelength λ2 is reflected. Furthermore, the long-wave pass means that the light of the first wavelength λ1 is reflected and the light of the second wavelength λ2 is transmitted.

Furthermore, a polarizer having a photonic crystal structure that separates a ratio of P-polarized light and S-polarized light may be provided inside the second resonator 12. Furthermore, it is possible to provide a diffraction grating inside the second resonator 12 to convert the polarization state of the emitted laser pulse from random polarization to linear polarization. The fine groove portion of the photonic crystal structure or the diffraction grating can be used as an interface for bonding by forming a film of a material such as SiO₂ and polishing the film.

### (Operation Principle of Laser Element 1)

Next, the operation of the laser element 1 of FIG. 1 will be described. By injecting a current into the active layer 7 via the electrode of the excitation light source 2, laser oscillation at the first wavelength λ1 occurs in the first resonator 11, and the solid-state laser medium 3 is excited. Since the saturable absorber 4 is bonded to the solid-state laser medium 3, in an initial stage when the laser oscillation at the first wavelength λ1 occurs, the spontaneous emission light from the solid-state laser medium 3 is absorbed by the saturable absorber 4, so that optical feedback by the fourth reflection layer R4 on the emission surface side of the saturable absorber 4 does not occur, and the Q-switched laser oscillation does not occur.

Thereafter, when the power of the excitation light of the first wavelength λ1 is accumulated in the solid-state laser medium 3, and the solid-state laser medium 3 comes into a sufficiently excited state, the output of the spontaneous emission light increase. When this exceeds a certain threshold, a light absorption rate in the saturable absorber 4 rapidly decreases, enabling the spontaneous emission light generated in the solid-state laser medium 3 to be transmitted through the saturable absorber 4. Therefore, the light of the first wavelength λ1 by the first resonator 11 is emitted from the solid-state laser medium 3, and the second resonator 12 causes the light of the second wavelength λ2 to resonate between the second reflection layer R2 and the fourth reflection layer R4. Therefore, the Q-switched laser oscillation occurs, and the Q-switched laser pulse is emitted toward a space (space on the right side in FIG. 1) via the fourth reflection layer R4.

A non-linear optical crystal for wavelength conversion can be disposed inside the second resonator 12. The wavelength of the laser pulse after the wavelength conversion can be changed depending on the type of the non-linear optical crystal. Examples of wavelength converting materials include non-linear optical crystals such as LiNbO₃, BBO, LBO, CLBO, BiBO, KTP, and SLT. Furthermore, a phase-matching material similar to these materials may be used as the wavelength converting material. Note that the type of the wavelength converting material is not limited. The second wavelength λ2 can be converted to another wavelength using the wavelength converting material.

Although the basic configuration and the operation principle for obtaining the Q-switched laser oscillation according to the present disclosure have been described above, the above basic configuration cannot prevent a decrease in the oscillation efficiency of the laser light and a decrease in the conversion efficiency of the optical wavelength due to thermal interference between the excitation light source and the solid-state laser medium.

### (Cause and Measure of Thermal Interference)

When the excitation light source 2 including the laminated semiconductor layer and the solid-state laser medium 3 are adjacent to each other or directly bonded to each other, the temperature of the excitation light source rises as the current flowing through the active layer 7 of the excitation light source 2 rises, and heat is transferred from the excitation light source 2 to the solid-state laser medium 3, causing the temperature of the solid-state laser medium 3 to rise. As a result, the conversion efficiency of the optical wavelength from the first wavelength to the second wavelength in the solid-state laser medium 3 decreases. On the other hand, when temperature of the solid-state laser medium 3 rises due to excitation light absorption, heat is transferred from the solid-state laser medium 3 to the excitation light source 2, and the temperature of the excitation light source 2 further rises. As a result, thermal interference between the excitation light source 2 and the solid-state laser medium 3 occurs, the I-L characteristic (light emission efficiency) of the excitation light source 2 deteriorates, a junction temperature Tj of the active layer 7 rises, and long-term reliability (mean time to failure: MTTF) deteriorates.

To inhibit thermal interference between the excitation light source 2 and the solid-state laser medium 3, it is desirable to provide a heat exhaust unit between the excitation light source 2 and the solid-state laser medium 3. The heat exhaust unit is, for example, a transparent material that can transmit light of the first wavelength and has higher thermal conductivity than the solid-state laser medium 3. In general, YAG having a thermal conductivity of 17 W/(m·K) is often used as the material of the solid-state laser medium 3. In particular, in a case where the base material size in the direction perpendicular to the optical axis of the solid-state laser medium 3 is sufficiently larger than the beam diameter (100 μm) (e.g., about several mm), the in-plane temperature gradient of the solid-state laser medium 3 increases. Therefore, it is effective to provide a material having high thermal conductivity in order to transfer heat in the side surface direction of the solid-state laser medium 3. For example, sapphire has a thermal conductivity of 40 W/(m·K), thus having a thermal conductivity higher than that of YAG, and has a refractive index and a thermal expansion coefficient equivalent to those of YAG. In addition, CVD diamond having a thermal conductivity of 1000 W/(m·K) or SiC having a thermal conductivity of 200 W/(m·K) may be used. As described above, there is a plurality of candidates for the material used for the heat exhaust unit, and the material is not limited to a specific material.

Furthermore, it is desirable that heat be conducted in an in-plane direction perpendicular to the optical axis of the laser element, a heat propagation path be provided to a support member (e.g., Cu having a thermal conductivity of 400 W/(m·K)) disposed around the excitation light source 2 and the solid-state laser medium 3, and heat be exhausted from the support member to the housing of the package of the laser element.

In the laser element according to the present disclosure, since the heat exhaust unit is disposed between the excitation light source 2 including the laminated semiconductor layer and the solid-state laser medium 3, it is possible to prevent a decrease in the oscillation efficiency of the laser light and a decrease in the conversion efficiency of the optical wavelength due to thermal interference without losing the advantage of the compact integrated structure.

Furthermore, it is necessary to make a lateral mode, which is a beam intensity distribution of the first wavelength of the first resonator 11, substantially the same as a lateral mode, which is a beam intensity distribution of the second wavelength of the second resonator 12, for mode coupling, thus maximizing the output of the oscillation light by the second resonator 12. Therefore, it is desirable to consider the cooling efficiency and the lateral mode coupling efficiency for the thickness of a heat exhaust unit 13 between the excitation light source 2 and the solid-state laser medium 3 forming a part of the resonator length of the first resonator 11.

Furthermore, only adjusting the thickness of the heat exhaust unit 13 to efficiently couple the lateral mode that is the beam intensity distribution of the first wavelength of the first resonator 11 and the lateral mode that is the beam intensity distribution of the second wavelength of the second resonator 12 may lead to in an increase in the thickness of the heat exhaust unit 13. As a result, the first resonator 11 becomes long, and a diffraction loss of the first wavelength occurs. In addition, the entire length of the laser element 1 also increases.

By filling a part of the first resonator 11 with a high refractive material and condensing the first wavelength, it is possible to efficiently couple the lateral mode that is the beam intensity distribution of the first wavelength and the lateral mode that is the beam intensity distribution of the second wavelength of the second resonator 12 without impairing the cooling performance and increasing the length of the first resonator 11, and to maximize the output of the oscillation light.

Furthermore, in the laser element according to the present disclosure, there is a possibility that oscillation light having a high peak intensity by the short-pulse Q-switched laser light of the second wavelength enters the integrally bonded excitation light source as return light. Since the excitation light source 2 is formed by a material having a small band gap, optical damage due to multiphoton absorption by short-pulse laser light is likely to occur. Therefore, it is desirable to arrange a plurality of short-wave pass filters (SWPFs) at a plurality of interfaces between the excitation light source 2 and the solid-state laser medium 3 while reducing the resonator length such that the return light does not enter the excitation light source 2.

Hereinafter, various modes of the heat exhaust unit will be described.

### (First Mode of Heat Exhaust Unit)

FIG. 2 is a schematic cross-sectional view of a laser element 1 including a heat exhaust unit 13 according to a first mode. The laser element 1 of FIG. 2 is placed on a submount substrate 91, and the submount substrate 91 is placed on a support substrate 92. The laser element 1 includes the excitation light source 2 including a laminated semiconductor layer, the heat exhaust unit 13, the solid-state laser medium 3, and a cooling member (second member) 14.

The excitation light source 2 of FIG. 2 has, for example, the same layer configuration as the excitation light source 2 of FIG. 1, but a detailed layer configuration is not illustrated in FIG. 2. By bringing the electrodes E1, E2 illustrated in FIG. 1 into contact with the submount substrate 91 and connecting the submount substrate 91 and the support substrate 92 by a bonding wire 16, a current flowing through the active layer 7 of the excitation light source 2 can be supplied from the support substrate 92 via the bonding wire 16.

The laser element 1 of FIG. 2 does not include the saturable absorber 4 of FIG. 1. Unlike FIG. 1, the second resonator 12 causes the light of the second wavelength λ2 to resonate between the second reflection layer R2 and the fourth reflection layer R4 in the solid-state laser medium 3. The fourth reflection layer R4 is disposed on the second surface F2 of the solid-state laser medium 3 or on the rear side of the optical axis with respect to the second surface F2.

The heat exhaust unit 13 of FIG. 2 is bonded to the end face of the excitation light source 2 and the end face of the solid-state laser medium 3, and heat generated by the excitation light source 2 and the solid-state laser medium 3 is transferred to the heat exhaust unit 13. The heat exhaust unit 13 includes, for example, a heat exhaust member (first member) 17 formed by a material having a thermal conductivity higher than the solid-state laser medium 3. The material of the heat exhaust member 17 is, for example, sapphire, diamond, or the like, but is not limited to a specific material.

The excitation light source 2, the heat exhaust unit 13, and the solid-state laser medium 3 are arranged on the same optical axis. The cooling member 14 is bonded to each side surface of the excitation light source 2, the heat exhaust unit 13, and the solid-state laser medium 3. The cooling member 14 is formed by a metal material having high thermal conductivity such as Cu. The cooling member 14 dissipates the heat transferred from the excitation light source 2 and the solid-state laser medium 3 to the heat exhaust unit 13. The cooling member 14 may be bonded to a package (not illustrated) to dissipate heat using the package.

In the laser element 1 of FIG. 2, heat generated by the excitation light source 2 and the solid-state laser medium 3 is transferred to the heat exhaust unit 13. The heat exhaust unit 13 exhausts the heat from the excitation light source 2 and the solid-state laser medium 3 to the cooling member 14. This makes it possible to inhibit the temperature rise of the excitation light source 2 and the solid-state laser medium 3. Therefore, according to the laser element 1 of FIG. 2, thermal interference between the excitation light source 2 and the solid-state laser medium 3 can be inhibited, a decrease in the oscillation efficiency of the laser light in the excitation light source 2 can be prevented, and a decrease in the conversion efficiency of the optical wavelength in the solid-state laser medium 3 can be prevented.

Note that the heat exhaust unit 13 may be an air gap that is provided between the excitation light source 2 and the solid-state laser medium 3 instead of providing the heat exhaust member 17. By arranging the excitation light source 2 and the solid-state laser medium 3 at a distance so as not to be in surface contact with each other, heat transfer can be inhibited, and thermal interference can be prevented. The cooling member 14 has not only a function of cooling the excitation light source 2 and the solid-state laser medium 3 but also a function of supporting the excitation light source 2 and the solid-state laser medium 3 while maintaining an air gap. Although air exists in the air gap portion, the thermal conductivity of the air is lower than the thermal conductivities of the excitation light source 2 and the solid-state laser medium 3, so that heat transfer between the excitation light source 2 and the solid-state laser medium 3 can be inhibited, and thermal interference between the excitation light source 2 and the solid-state laser medium 3 can be prevented.

### (Second Mode of Heat Exhaust Unit 13)

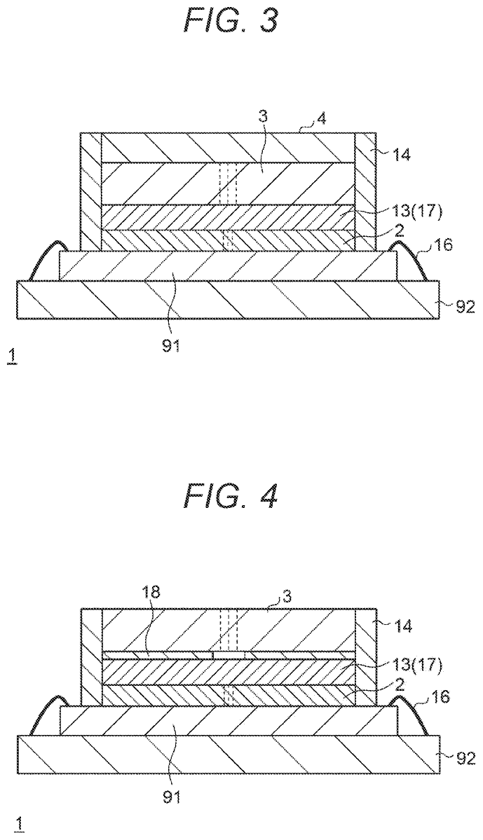

FIG. 3 is a schematic cross-sectional view of a laser element 1 including a heat exhaust unit 13 according to a second mode. The laser element 1 of FIG. 3 is obtained by adding the saturable absorber 4 to the laser element 1 of FIG. 2. As illustrated in FIG. 3, the saturable absorber 4 is bonded to the end face of the solid-state laser medium 3. Similarly to FIG. 1, the second resonator 12 in the laser element 1 of FIG. 3 causes the light of the second wavelength λ2 to resonate between the second reflection layer R2 in the solid-state laser medium 3 and the fourth reflection layer R4 in the saturable absorber 4.

Since the laser element 1 of FIG. 3 includes the heat exhaust unit 13 similar to that of FIG. 2, thermal interference between the excitation light source 2 and the solid-state laser medium 3 can be inhibited.

### (Third Mode of Heat Exhaust Unit 13)

FIG. 4 is a schematic cross-sectional view of a laser element 1 including a heat exhaust unit 13 according to a third mode. In the laser element 1 of FIG. 4, the heat exhaust unit 13 has a two-layer structure, and a metal layer 18 having high thermal conductivity such as Cu is disposed on the surface of the heat exhaust member 17 such as sapphire. The metal layer 18 is formed on the heat exhaust member 17 by, for example, vapor deposition or sputtering. Since the cooling member 14 is bonded to the side surfaces of the cooling member 14, the heat exhaust unit 13, and the solid-state laser medium 3, by disposing the metal layer 18 on the surface of the heat exhaust member 17, heat from the solid-state laser medium 3 can be efficiently transferred to the heat exhaust member 17 and the cooling member 14 via the metal layer 18, and the heat exhaust performance of the heat exhaust unit 13 is further improved. However, heat is generated when the light of the first wavelength is absorbed by the metal layer, and it is thus necessary to avoid the optical path of the first wavelength.

Although the laser element 1 of FIG. 4 does not include the saturable absorber 4, similarly to FIG. 3, k the saturable absorber 4 may be bonded to the end face of the solid-state laser medium 3.

### (Fourth Mode of Heat Exhaust Unit 13)

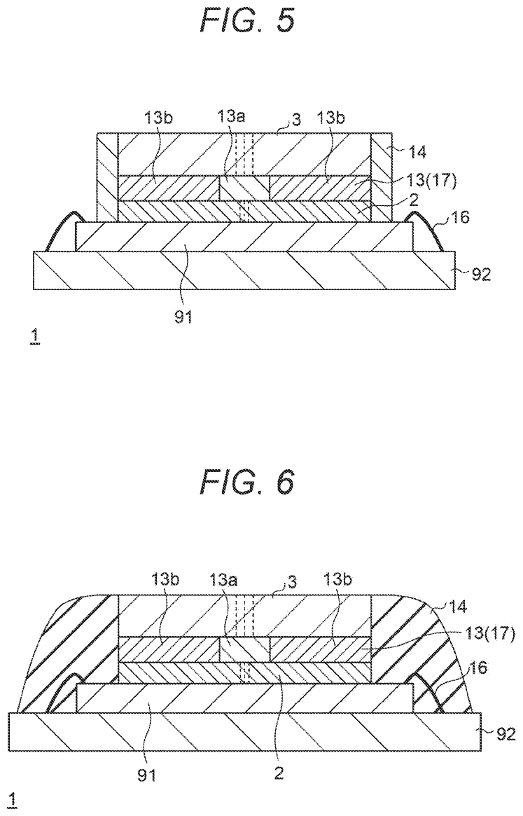

FIG. 5 is a schematic cross-sectional view of a laser element 1 including a heat exhaust unit 13 according to a fourth mode. In the laser element 1 of FIG. 5, the structure of the heat exhaust unit 13 is different from those of the first to third modes. The heat exhaust unit 13 of FIG. 5 has a first region 13a and a second region 13b. The first region 13a is a region including the optical axis, and is disposed substantially at the center of the heat exhaust unit 13. The first region 13a is a region that transmits the light of the first wavelength. The first region 13a may be a transparent material layer that transmits the light of the first wavelength, or may be a simple air gap. The second region 13b is a region disposed around the first region 13a and having a thermal conductivity higher than the solid-state laser medium 3. The second region 13b may be arranged as a plurality of vias. In a case where the first region 13a is an air gap, the second region 13b functions as a spacer member for supporting the air gap of the first region 13a. The second region 13b is formed by an insulating material or a metal material, and is formed by a material having high thermal conductivity such as sapphire or diamond.

The heat generated by the excitation light source 2 and the solid-state laser medium 3 is exhausted in the second region 13b in the heat exhaust unit 13. Since the second region 13b is bonded to the excitation light source 2 and the solid-state laser medium 3 and is also bonded to the cooling member 14, the heat transmitted from the excitation light source 2 and the solid-state laser medium 3 can be exhausted to the cooling member 14.

The second region 13b may be formed in an annular shape so as to surround the first region 13a, or may include a plurality of vias.

### (Fifth Mode of Heat Exhaust Unit 13)

FIG. 6 is a schematic cross-sectional view of a laser element 1 including a heat exhaust unit 13 according to a fifth mode. In the laser element 1 of FIGS. 2 to 5, a current is injected into the active layer 7 of the laser element 1 by the bonding wire 16. The bonding wire 16 is generally covered with a protective layer to prevent cutting. In the laser element 1 of FIG. 6, the protective layer of the bonding wire 16 and the cooling member 14 are integrated. Hereinafter, this integrated member will be referred to as a cooling member 14. The cooling member 14 of FIG. 6 is disposed to cover the bonding wire 16 as well as being in contact with the side surfaces of the excitation light source 2, the heat exhaust member 17, and the solid-state laser medium 3. The protective layer of the bonding wire 16 of FIG. 6 is desirably covered with an insulating material. As the insulating coating material, a resin material, a glass material, or the like is known, and the insulating coating material is not limited to a specific material as long as it is an insulating material. The thermal conductivity of the cooling member 14 only needs to be a material higher than that of the solid-state laser medium 3, and is not limited to a specific material.

Note that a protective layer may be provided to cover the side surface of the cooling member and the bonding wire 16 in FIG. 5. In this case, the protective layer is provided separately from the cooling member.

### (Sixth Mode of Heat Exhaust Unit 13)

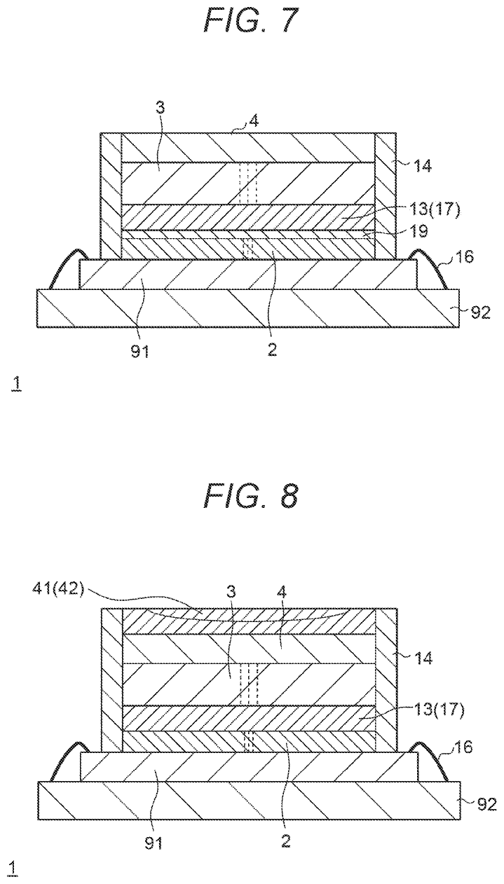

FIG. 7 is a schematic cross-sectional view of a laser element 1 including a heat exhaust unit 13 according to a sixth mode. The laser element 1 of FIG. 7 is different from the heat exhaust units 13 of FIGS. 2 and 4 in the layer configuration of the heat exhaust unit 13. The heat exhaust unit 13 of FIG. 7 has a protective layer 19 laminated on the surface on the side facing the laminated semiconductor layer 2. The protective layer 19 functions as a layer that transmits light of the first wavelength λ1 and reflects light of the second wavelength λ2.

By providing the heat exhaust unit 13 with the protective layer 19, light leaking from the second resonator 12 can be inhibited, and the light emission efficiency of the excitation light source 2 and the conversion efficiency of the optical wavelength of the solid-state laser medium 3 can be improved.

### (Seventh Mode of Heat Exhaust Unit 13)

FIG. 8 is a schematic cross-sectional view of a laser element 1 including a heat exhaust unit 13 according to a seventh mode. A part of the energy of the excitation light absorbed by the solid-state laser medium 3 in the laser element 1 according to the present disclosure is converted into heat, and the temperature of the solid-state laser medium 3 rises. At this time, a temperature distribution is generated in the solid-state laser medium 3, and a refractive index distribution associated with the temperature distribution is generated. In general, as the temperature rises, the refractive index of many solid-state laser media 3 formed by an inorganic material increase, and the refractive index of the peripheral portion decreases gradually. As a result, a virtual condenser lens called a thermal lens is formed in the solid-state laser medium 3. Due to this thermal lens effect, the laser light is condensed inside the second resonator 12. Inside the second resonator 12, the peak intensity of the laser light is higher due to the shorter pulse, so that optical damage inside the first resonator and the second resonator 12 is likely to occur more remarkably caused by the condensing of the laser light by the thermal lens effect. Especially, the laminated semiconductor layer forming the first resonator includes a material having a small band gap, and therefore, the optical damage caused by multiphoton absorption is likely to occur when leaked light of the laser light of the second wavelength λ2 generated in the second resonator 12 enters the first resonator.

Therefore, the laser element 1 of FIG. 8 includes an optical element 41 that increases the beam diameter of the laser light of the second wavelength λ2 generated by the second resonator 12, in addition to the heat exhaust unit 13. The optical element 41 is disposed between the second reflection layer R2 and the fourth reflection layer R4 of the solid-state laser medium 3. In a case where the laser element 1 does not include the saturable absorber 4, the fourth reflection layer R4 is disposed on the end face on the light emission surface side of the solid-state laser medium 3 or on the rear side of the optical axis with respect to the end face. Furthermore, in a case where the laser element 1 includes the saturable absorber 4, the laser element 1 is disposed on the end face on the light emission surface side of the saturable absorber 4 or on the rear side of the optical axis with respect to the end face.

The optical element 41 reflects or refracts at least a part of the light of the second wavelength λ2 so that the light of the second wavelength λ2 is not condensed. More specifically, the optical element 41 includes, for example, a convex mirror that reflects at least a part of the incident light or a light refracting member that refracts at least a part of the incident light so that the incident light is not condensed.

In the example of FIG. 8, an example is illustrated in which the optical element 41 is provided on the end face on the light emission surface side of the saturable absorber 4. In the optical element 41, the end face on the solid-state laser medium 3 side of a base material of a material that transmits the light of the first wavelength and the light of the second wavelength λ2 is processed into a concave shape, and a multilayer film is formed along the concave surface, for example, to dispose a convex mirror 42. The convex mirror 42 functions as the fourth reflection layer R4 of the second resonator 12. The light of the second wavelength λ2 incident on the convex mirror 42 is reflected so as not to be condensed. As a result, the beam diameter of the light of the second wavelength λ2 in the second resonator 12 can be increased, the peak power of the laser light can be reduced, and optical damage is less likely to occur in the solid-state laser medium 3 and the excitation light source 2. In FIG. 8, the heat exhaust member 17 is provided on the lower surface of convex mirror 42, and the side of heat exhaust member 17 bonded to convex mirror 42 is processed into a concave shape.

### (Eighth Mode of Heat Exhaust Unit 13)

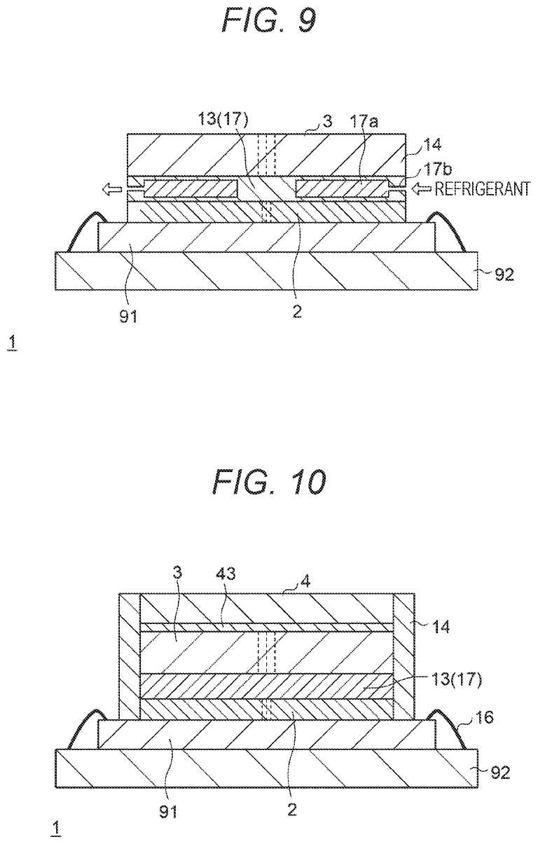

FIG. 9 is a schematic cross-sectional view of a laser element 1 including a heat exhaust unit 13 according to an eighth mode. The heat exhaust unit 13 in the laser element 1 of FIG. 9 includes the heat exhaust member 17 having a positive cooling function. For example, the heat exhaust member 17 has a function of storing and circulating a refrigerant 17a, and as a specific mounting example, a mode is conceivable which the excitation light optical axis portion is a transparent member, and a heat pipe 17b storing the refrigerant is provided around the excitation light optical axis portion. Furthermore, a mode is also conceivable in which the heat exhaust member 17 is provided with a fine flow path communicating with the outside of the laser element instead of the heat pipe 17b, and the refrigerant 17a is circulated. Forcibly cooling with the refrigerant 17a enables the laser medium 3 to efficiently exhaust heat. The refrigerant 17a may be liquid or gas.

### (Ninth Mode of Heat Exhaust Unit 13)

FIG. 10 is a schematic cross-sectional view of a laser element 1 including a heat exhaust unit 13 according to a ninth mode. The laser element 1 of FIG. 10 includes a light control member (polarization control element) 43 in addition to the heat exhaust unit 13. The light control member 43 is disposed, for example, between the solid-state laser medium 3 and the saturable absorber 4 or on the rear side of the optical axis with respect to the saturable absorber 4. The light control member 43 controls refraction, diffraction, or a polarization direction of the light of the second wavelength λ2. More specifically, the light control member 43 is, for example, a photonic crystal layer. The photonic crystal layer is a layer in which the refractive index changes periodically Furthermore, in the photonic crystal layer, either P-polarized light or S-polarized light can be selected. Furthermore, the light control member 43 may be a diffraction grating.

The light control member 43 may include a fine periodic structure. More specifically, the fine periodic structure is, for example, a Fresnel lens, a meta-surface structure, or a photonic crystal lens. The refraction, diffraction, or polarization direction of the light of the second wavelength λ2 can be controlled by adjusting the period or size of the irregularities forming the fine periodic structure.

### (Tenth Mode of Heat Exhaust Unit 13)

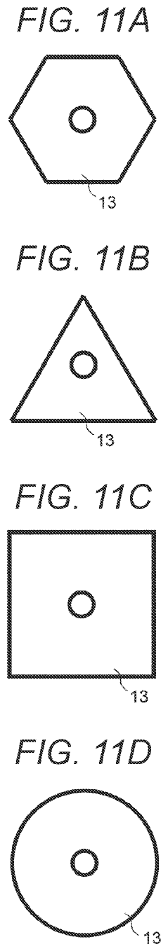

FIGS. 11A, 11B, 11C, and 11D are views schematically illustrating a planar shape of a heat exhaust unit 13 according to a tenth mode. The heat exhaust unit 13 illustrated in each of FIGS. 11A to 11C includes the heat exhaust unit 13 according to any one of the first to eighth modes as a basic structure, and is obtained by adding an additional technical feature to the basic structure. In heat exhaust unit 13 illustrated in the of FIGS. 11A to 11C, the optical axis of the laser light is disposed at the center position of cooling member 14 having a polygonal planar shape. Around the optical axis of the laser light, the heat exhaust member 17 such as sapphire may be disposed, or may be an air gap. The portion of the optical axis of the laser light has the highest temperature, and hence it is desirable to have a structure in which heat is uniformly transferred to the heat exhaust member 17 disposed around the portion. Therefore, in FIGS. 11A to 11C, the planar shape of the cooling member 14 is a regular n-polygon (n is an integer of 3 or more), and the center position of the regular n-polygon is the optical axis of the laser element 1. Furthermore, in the heat exhaust unit 13 illustrated in FIG. 11D, the optical axis of the laser light is disposed at the center position of the cooling member 14 having a circular planar shape. As a result, the distance from each of the vertices of the regular n-polygonal shape or the circular shape to the optical axis is equal, and the heat is uniformly transferred to the entire region of the heat exhaust unit 13, enabling efficient heat dissipation through the cooling member 14

### (Eleventh Mode of Heat Exhaust Unit 13)

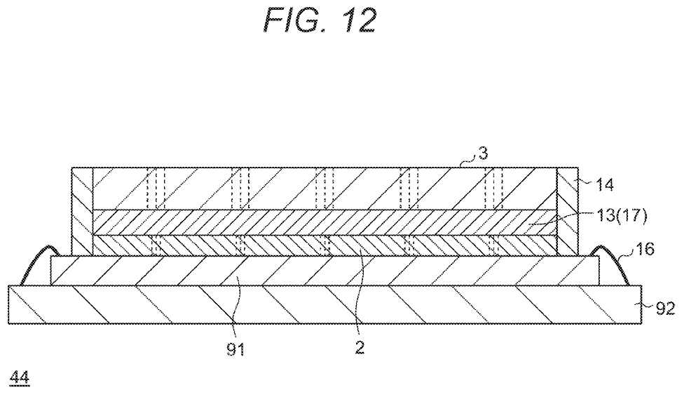

FIG. 12 is a schematic cross-sectional view of a laser array 44 in which a plurality of lens elements is arranged in a one-dimensional direction or a two-dimensional direction. FIG. 12 illustrates an example in which each lens element includes the heat exhaust unit 13 having a similar structure to that in FIG. 2, but the lens element may include the heat exhaust unit 13 according to any one of the second to tenth modes. The heat exhaust unit 13 included in each of the plurality of lens elements is integrally bonded. The heat exhaust unit 13 having the integral structure includes the heat exhaust member 17. The cooling member 14 is bonded to the side surface of a lens array having the plurality of lens elements. The cooling member 14 is bonded to the heat exhaust member 17. As a result, heat generated in the excitation light source 2 and the solid lens medium in each lens element is transferred to the heat exhaust member 17, and is dissipated from the heat exhaust member 17 to the cooling member 14.

### (Temperature Distribution of Heat Exhaust Unit 13)

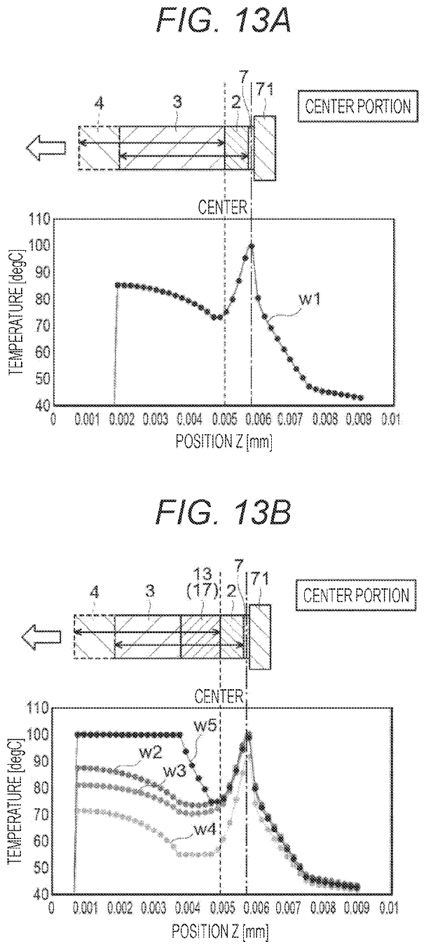

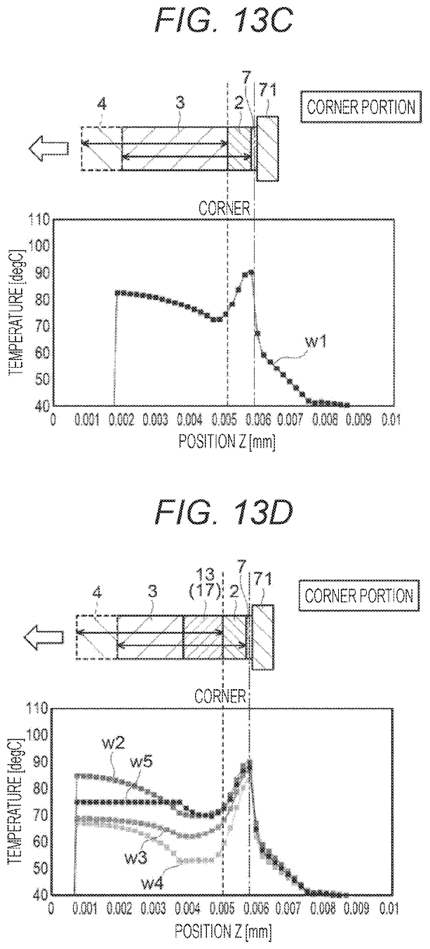

FIGS. 13A, 13B, 13C, and 13D are diagrams each illustrating a temperature distribution of the laser light source at the center portion or the corner portion of the laser array 44 in a case where the heat exhaust unit 13 is provided or in a case where the heat exhaust unit is not provided. FIGS. 13A and 13B each illustrate the temperature distribution of the laser light source at the center portion of the laser array 44. FIG. 13A illustrates a case where the heat exhaust unit 13 is not provided, and FIG. 13B illustrates a case where the heat exhaust unit 13 is provided. Furthermore, FIGS. 13C and 13D each illustrate the temperature distribution of the laser light source at the corner portion of the laser array 44. FIG. 13C illustrates a case where the heat exhaust unit 13 is not provided, and FIG. 13D illustrates a case where the heat exhaust unit 13 is provided.

The horizontal axis in each of FIGS. 13A to 13D indicates the position on the optical axis of the laser element 1, the fourth reflection layer R4 side of the solid-state laser medium 3 is the left side of the horizontal axis, and the support substrate 92 side is the right side of the horizontal axis. The vertical axis in each of FIGS. 13A to 13D represents the temperature at each position. FIGS. 13A and 13C illustrate the temperature distribution w1 of the laser element 1 without the heat exhaust unit 13. FIGS. 13B and 13D illustrate temperature distributions w2 to w5 of four types of laser elements 1 having different heat exhaust units 13. The temperature distribution w2 indicates a temperature distribution of the heat exhaust unit 13 having the heat exhaust member 17 formed by sapphire, the temperature distribution w3 indicates a temperature distribution of the heat exhaust unit 13 having the heat exhaust member 17 formed by sapphire and the cooling member 14, the temperature distribution w4 indicates a temperature distribution of the heat exhaust unit 13 having the heat exhaust member 17 formed by diamond and the cooling member 14, and the temperature distribution w5 indicates a temperature distribution of the laser element 1 having the heat exhaust unit 13 having the air gap and the cooling member 14. The cooling member 14 is a copper wall bonded to the side surfaces of the excitation light source 2, the heat exhaust unit 13, and the solid-state laser medium 3.

As illustrated in the drawing, the temperature of the laser element 1 at the center portion of the laser array 44 is higher than the temperature of the laser element 1 at the corner portion of the laser array as a whole regardless of whether or not the heat exhaust unit 13 is provided. Furthermore, among the four types of heat exhaust units 13, the laser element 1 (temperature distribution w5) that includes the heat exhaust unit 13 with the heat exhaust member 17 formed by diamond and the cooling member 14 have the largest temperature reduction effect. The laser element 1 (temperature distribution w4) that includes the heat exhaust unit 13 with the heat exhaust member 17 formed by sapphire and the cooling member 14 has the second largest temperature reduction effect, and the laser element 1 (temperature distribution w3) that includes the heat exhaust unit 13 with the heat exhaust member 17 formed by sapphire and includes no cooling member 14 has the second largest temperature reduction effect. The laser element 1 (temperature distribution w2) that includes the heat exhaust unit 13 with the air gap and the cooling member 14 has the smallest temperature reduction effect, but even the laser element 1 only including the air gap can reduce the temperature more than the laser element 1 (temperature distribution w1) including no air gap. Therefore, the heat exhaust unit 13 can obtain a certain degree of effect of inhibiting the temperature rise in the laser element 1 only with the air gap.

### (Countermeasure Against Return Light)

Furthermore, when the second resonator 12 emits the laser pulse of the second wavelength λ2 using the Q-switch, there is a possibility that oscillation light of the second wavelength λ2 with high peak intensity enters the excitation light source 2 as return light. Since the excitation light source 2 is formed by a semiconductor material having a small band gap, this might be broken by the return light. Therefore, it is desirable to arrange a plurality of short-wave pass filters (SWPFs) as the heat exhaust unit 13 and the protective layer 19 between the excitation light source 2 and the solid-state laser medium 3 while reducing the resonator length, thereby preventing the return light from entering the excitation light source 2.

### (Manufacturing Method for Laser Element 1 of Present Disclosure)

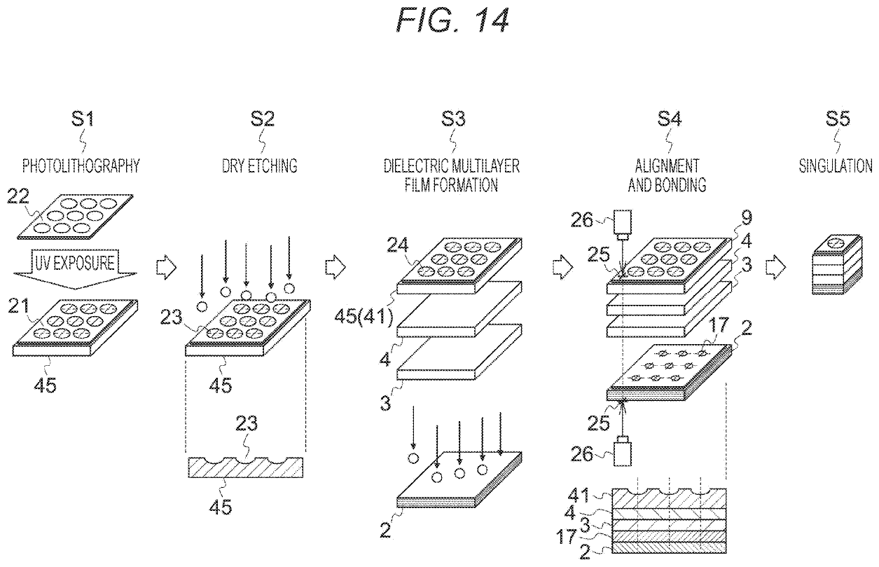

FIG. 14 is a view schematically illustrating the manufacturing process of the laser element 1 of the present disclosure. FIG. 14 illustrates the manufacturing process of the laser element 1 including the optical element 41 and the saturable absorber 4 for avoiding optical damage illustrated in FIG. 8. Furthermore, FIG. 14 illustrates an example in which the convex mirror 42 for the optical element 41 is formed on the upper surface side of the saturable absorber.

First, as illustrated in step S1 of FIG. 10, a resist film 21 is applied onto a transparent base material 45 for the optical element 41 placed on the saturable absorber 4, a photomask 22 is disposed on the resist film 21, and ultraviolet (UV) exposure is performed.

Next, as described in step S2, the exposed portion and the resist film 21 are removed by dry etching or the like to form a plurality of recesses 23 on the upper surface of the transparent base material 45. In the plurality of recesses 23, a dielectric multilayer film 24 is formed by vapor deposition, sputtering, or the like to form convex mirror 42.

Next, as described in step S3, the laminated semiconductor layer 2 for the excitation light source 2, the heat exhaust member 17, the solid-state laser medium 3, and the saturable absorber 4 processed in step S2 are arranged and aligned in the vertical direction. Note that the heat exhaust member 17 is formed by depositing sapphire, diamond, or the like on the upper surface of the laminated semiconductor layer 2 by vapor deposition or sputtering before step S3.

At that time, as described in step S4, the semiconductor layer 2, the solid-state laser medium 3, and the saturable absorber 4 are aligned and bonded so that alignment marks 25 are vertically overlapped by, for example, photographing the alignment marks 25 provided at specific locations of the semiconductor layer 2, the solid-state laser medium 3, and the saturable absorber 4 with a camera 26. Next, as shown in step S5, singulation is performed by dicing into individual laser elements.

### (Effect of Laser Element 1 of Present Disclosure)

As described above, in the laser element 1 of the present disclosure, since the heat exhaust unit 13 is provided between the excitation light source 2 and the solid-state laser medium 3, heat generated in at least one of the excitation light source 2 or the solid-state laser medium 3 can be discharged. In particular, the heat generated by the excitation light source 2 and the solid-state laser medium 3 can be efficiently exhausted by using, as the heat exhaust unit 13, the heat exhaust member 17 formed by a material having a higher thermal conductivity than the solid-state laser medium 3 such as sapphire or diamond. Furthermore, by bonding the cooling member 14 formed by Cu or the like to the side surfaces of the excitation light source 2, the heat exhaust unit 13, and the solid-state laser medium 3, the heat generated by the excitation light source 2 and the solid-state laser medium 3 can be dissipated to the cooling member 14 via the heat exhaust member 17, and a temperature rise in the laser element 1 can be inhibited.

In the laser element 1 according to the present disclosure, the first resonator 11 and the second resonator 12 share the solid-state laser medium 3. Furthermore, the light transmission surfaces of all the optical components including the excitation light source 2, the solid-state laser medium 3, and the saturable absorber 4 in the laser element 1 are bonded and fixed by the bonding process. Moreover, by providing the heat exhaust unit 13 described above between the excitation light source 2 and the solid-state laser medium 3, it is possible to inhibit a temperature rise in the laser element 1. As a result, the reliability and mass productivity of the laser element 1 are improved, and the laser element 1 having high performance at low cost can be obtained.

According to the present disclosure, the solid-state laser medium 3 is bonded to the excitation light source 2, the solid-state laser medium 3 is excited by a standing wave in the excitation light source 2. By designing a resonator that confines the excitation light inside the first resonator 11, even in a case where the solid-state laser medium 3 has such a thickness that a single passage of the laser light in the first resonator 11 does not lead to full absorption, the laser light can be reciprocated many times, and finally the excitation light can be sufficiently absorbed by the solid-state laser medium 3. This makes it possible to perform Q-switched laser oscillation with a shorter pulse without reducing excitation efficiency.

In the conventional Q-switched solid-state laser, the solid-state laser medium 3 is excited by a traveling wave, and how to excite is greatly different from that of the laser element 1 according to the present disclosure. In the laser element 1 according to the present disclosure, it is possible to solve the above-described trade-off that the amount of excitation light absorbed decreases when the solid-state laser medium 3 is reduced.

Furthermore, according to the laser element 1 of the present disclosure, it is possible to inhibit short-term and long-term fluctuations in laser output due to mechanical positional deviation by directly bonding the light transmission surface of each optical component. Furthermore, since all the optical components can be bonded and then diced into individual laser light sources, mass productivity can be improved.

Conventionally, the excitation light source 2 and the second resonator 12 perform five-axis optical adjustment (X, Y, Z, θ, φ) with respect to the optical axis, eccentricity, and focus using a plurality of lenses including a collimator lens and a condenser lens. Furthermore, when it is attempted to add an optical element 9 having a beam divergence function (negative refractive power) to the second resonator 12, it becomes more difficult to accurately adjust the position of the optical element 9.

However, in the laser element 1 according to the present disclosure, in order to align the light emission point of the excitation light source 2 and the center position of the convex mirror 42 of the optical element 9 without using the plurality of lenses, which are the collimator lens and the condenser lens, bonding is performed by using the alignment mark 25 and the like, so that it is not necessary to adjust the focus position accuracy in the thickness (Z-axis) direction or the inclination in the θ and φ directions. Therefore, the laser element 1 of the present disclosure makes it possible to inhibit the short-term and long-term fluctuations in laser output, facilitates optical adjustment due to the oscillation light obtained from the excitation light source 2, and implements the light source with improved mass productivity.

Furthermore, the laser element 1 according to the present disclosure adopts a laminated structure in which the optical axis of the first resonator 11 and the optical axis of the second resonator 12 are integrated so as to be coaxial. In the laser element 1 according to the present disclosure, it is not necessary to perform complicated position and angle alignment, and the structure is simplified. This facilitates the size reduction of the laser element 1.

Furthermore, a plurality of laser elements 1 according to the present disclosure can be simultaneously formed by laminating or bonding a plurality of materials on the same semiconductor substrate 5. By dicing in a post-process after the plurality of laser elements 1 is simultaneously formed to separate each laser element 1, it is possible to mass-produce high-performance laser elements 1 at a low cost. Furthermore, according to the laser element 1 of the present disclosure, it is possible to easily fabricate the laser array 44 in which the plurality of laser elements 1 is two-dimensionally arranged on one substrate.

Furthermore, in the laser element 1 according to the present disclosure, a repetition frequency of the laser pulse can be adjusted depending on the type of the solid-state laser medium 3. Especially, the laser element 1 according to the present disclosure has a high gain density, thus enabling an increase in the repetition frequency of the laser pulse. Furthermore, in the laser element 1 according to the present disclosure, the resonator length can be changed only by adjusting the thicknesses of the solid-state laser medium 3, the Q-switch (the saturable absorber 4), and the wavelength converting material (the non-linear optical crystal). That is, since the pulse time width of the laser pulse can be changed depending on the thickness of the material, the characteristic of the laser pulse can be easily adjusted. Especially, reducing the pulse time width of the laser pulse can increase processing accuracy in the field of fine processing.

Moreover, arraying the laser elements 1 according to the present disclosure in a one-dimensional array or a two-dimensional array makes it possible to obtain a laser device that achieves both high processing accuracy and high output energy. Furthermore, the laser element 1 according to the present disclosure can be applied to other fields such as highly efficient wavelength conversion technology, medical equipment, and ranging.

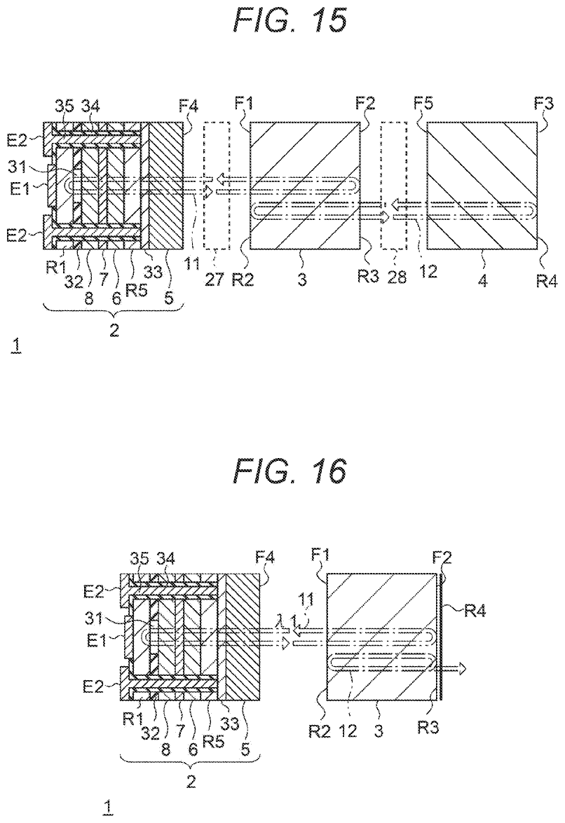

The laser element 1 of FIG. 1 has illustrated an example in which the excitation light source 2, the solid-state laser medium 3, and the saturable absorber 4 are integrally bonded. However, as illustrated in FIG. 15, a first transparent medium 27 that transmits the light of the first wavelength λ1 may be disposed between the excitation light source 2 and the solid-state laser medium 3.

Furthermore, as illustrated in FIG. 15, a second transparent medium 28 that transmits the light of the second wavelength λ2 may be disposed between the solid-state laser medium 3 and the saturable absorber 4. Note that only one of the first transparent medium 27 and the second transparent medium 28 may be disposed.

In this manner, the excitation light source 2, the solid-state laser medium 3, and the saturable absorber 4 are not necessarily integrally bonded.

Furthermore, as illustrated in FIG. 15, the optical element 9 may be disposed on the rear side of the optical axis with respect to the saturable absorber 4. In the optical element 9 of FIG. 15, a transparent member 29 that transmits the light of the second wavelength λ2 is processed into a concave shape to form the convex mirror 42. In the case of FIG. 15, the optical axis of the excitation light source 2, the optical axis of the solid-state laser medium 3, the optical axis of the saturable absorber 4, and the optical axis of the optical element 9 need to be arranged coaxially.

### (Laser Element 1 Not Including Saturable Absorber 4)

FIG. 1 has illustrated an example in which the laser element 1 includes the saturable absorber 4 and emits the short-pulse pulsed laser light. However, even in the laser element 1 that does not include the saturable absorber 4 and emits the CW laser light, thermal interference may occur between the excitation light source 2 and the solid-state laser medium.

FIG. 16 is a diagram illustrating a basic configuration of the laser element 1 not including the saturable absorber 4. The laser element 1 of FIG. 16 has a configuration in which the saturable absorber 4 is omitted from FIG. 1. Similarly to FIG. 1, the first resonator 11 causes the light of the first wavelength λ1 to resonate between the first reflection layer R1 in the excitation light source 2 and the third reflection layer R3 in the solid-state laser medium 3. On the other hand, unlike FIG. 1, the second resonator 12 causes the light of the second wavelength λ2 to resonate between the second reflection layer R2 and the fourth reflection layer R4 in the solid-state laser medium 3. The fourth reflection layer R4 is disposed on the second surface F2 of the solid-state laser medium 3 or on the rear side of the optical axis with respect to the second surface F2.

FIG. 16 illustrates an example in which the third reflection layer R3 and the fourth reflection layer R4 are separately provided along the second surface F2 of the solid-state laser medium 3. In a case where the fourth reflection layer R4 is disposed on the rear side of the optical axis with respect to the third reflection layer R3 as in FIG. 16, the third reflection layer R3 needs to have a characteristic of transmitting the light of the second wavelength λ2.

The third reflection layer R3 is a high reflection layer, whereas the fourth reflection layer R4 is a partial reflection layer. Therefore, the power of the excitation light of the first wavelength is confined in the solid-state laser medium 3, and when the solid-state laser medium 3 comes into a sufficiently excited state and the output of the spontaneous emission light increases, the light of the second wavelength λ2 is transmitted through the fourth reflection layer R4 to be emitted from the laser element 1.

Note that the third reflection layer R3 and the fourth reflection layer R4 may be integrated into one reflection layer. In this case, the integrated reflection layer reflects the light of the first wavelength and reflects the light of the second wavelength λ2.

The configuration in which the heat exhaust unit 13 is provided between the excitation light source 2 and the solid-state laser medium 3 in the laser element 1 of FIG. 16 is, for example, as illustrated in FIG. 2, FIG. 4, FIG. 5, FIG. 6, or FIG. 9.

### (Laser Amplification Element)

The structure of the laser element 1 according to the present disclosure described above can be applied to a laser amplification element. Conventionally, in order to avoid optical damage, a method of amplifying the short-pulse laser light by reducing the peak intensity of the amplified light has been devised and implemented. For example, there are a chirped-pulse amplification method in which the pulse width of the laser light is once expanded and amplification is performed in that state, and then the pulse width is compressed, a thin disk type method or a slab type method in which the beam of the laser light is spatially expanded to reduce the peak intensity, and the like. However, all of these methods require a huge and complicated optical method, and it is thus difficult to reduce the size and cost.

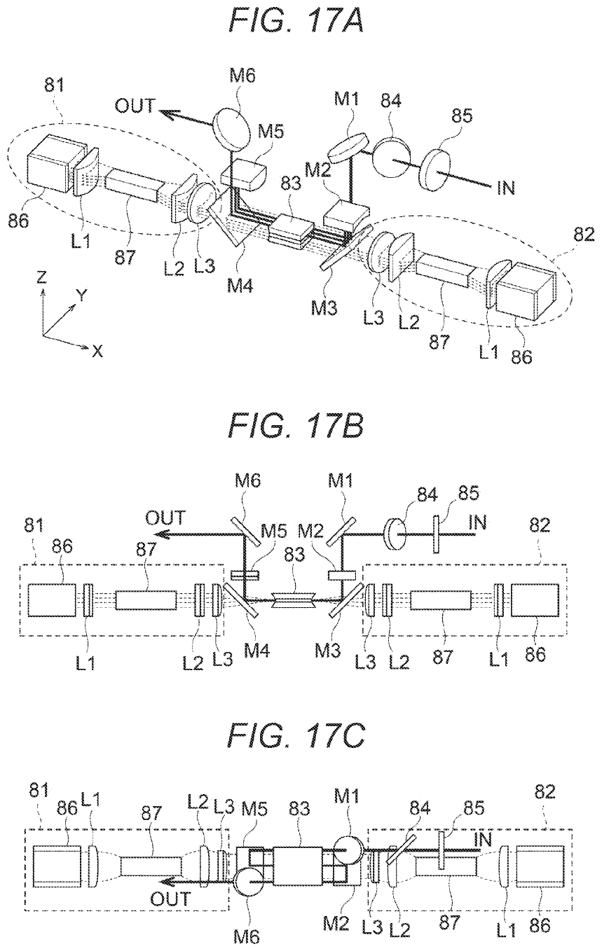

In particular, the Innoslab technology (developed by the Fraunhofer Institute in Germany and commercialized by EdgeWave GmbH and Amphos GmbH in Germany), an amplifier with a slab-type structure, has become a hot topic in recent years as a technology for increasing the output of laser light. FIG. 17A is a perspective view illustrating a configuration of Innoslab, FIG. 17B is a plan view of FIG. 17A as viewed from the Y direction, and FIG. 17C is a plan view of FIG. 17A as viewed from the Z direction.

As illustrated in these drawings, the Innoslab includes two excitation light sources 81, 82 provided on both sides in the X direction, mirrors M1 to M6, an amplification medium 83, a polarizer 84, and a λ/4 plate 85. Each of the excitation light sources 81, 82 includes a laser array 86, optical systems L1 to L3, and a waveguide 87.

From the input unit IN, weak light (light to be amplified) having amplification symmetry is incident. The light to be amplified is reciprocated between the mirrors M2 and M5 many times while gradually shifting its path. Each time the amplified light passes through the amplification medium 83 disposed between the mirrors M2 and M5, the amplified light is amplified by induced emission in the amplification medium 83, and finally the amplified laser light is emitted from the output unit OUT.

A plurality of laser arrays 86 in the excitation light sources 81, 82 is laminated in the Z direction, and planarly emit laser light in the X direction. The laser light planarly emitted from the laser array 86 is condensed by the cylindrical lens L1 and is incident on the waveguide 87. The laser light emitted from the waveguide 87 is beam-shaped by the cylindrical lens L2 and the optical system L3, and is incident on the half mirror M4. A part of the laser light incident on the half mirror M4 is transmitted through the half mirror M4 and is incident on the amplification medium 83.

In many cases, Nd:YAG or Yb:YAG is used as the amplification medium 83. The amplification medium 83 has a thin plate shape (e.g., 0.2 mm×10 mm×10 mm), and light to be amplified is incident on a rectangular elongated end face. The light to be amplified is so-called seed light, and is a laser pulse emitted from a femtosecond laser or a picosecond laser oscillator.

The Innoslab illustrated in FIGS. 17A to 17C has two advantages. A first advantage is that since the heat flux in the amplification medium 83 is one-dimensional, a thermal lens or thermal birefringence that limits the amplification magnification of the laser light does not occur. The thermal lens and the thermal birefringence remarkably occur in the rod type amplification medium 83, which has been a cause of limiting the amplification factor of the laser light.

A second advantage is that since the seed light is incident from the elongated rectangular end face described above, the beam shape of the seed light can be lengthened in the longitudinal direction, and optical damage due to the amplified light can be avoided by spatially decreasing the peak intensity in the amplification medium 83.

On the other hand, Innoslab has disadvantages. As illustrated in FIGS. 17A to 17C, in the Innoslab, a configuration in which excitation is performed from both sides of the amplification medium 83 is generally employed, and the length in the longitudinal direction is nearly 1 m. This is because a complicated beam-shaping optical system is required for forming a beam such that a light flux of an LD module emitted from the end face matches the rectangular end face of the amplification medium 83.

Furthermore, as a more theoretical problem, the amplification magnification of the laser light in the Innoslab is determined by the area in a case where the thickness of the amplification medium 83 is constant, but the area is determined by the light absorption length of the excitation light in the amplification medium 83. This is due to the fact the principle of the Innoslab method is a so-called end pump type amplifier configuration, and the amplification magnification of the laser light has a limit determined by the light absorption length of the excitation light.

For example, when Yb:YAG is used as the amplification medium 83 and the wavelength of the excitation light is 940 nm, the excitation light is absorbed at about 5 mm from the incident surface of Yb:YAG. To excite Yb:YAG from both sides, the length of Yb:YAG is set to about 10 mm. When the length of Yb:YAG is longer than 10 mm, an unexcited region is generated inside Yb:YAG. Therefore, in the amplification medium 83, only an amplification factor of a length determined by the absorption length of the excitation light can be obtained. Therefore, the upper limit of the amplification factor is determined by the size of the amplification medium 83, which is determined by the absorption length of the excitation light.

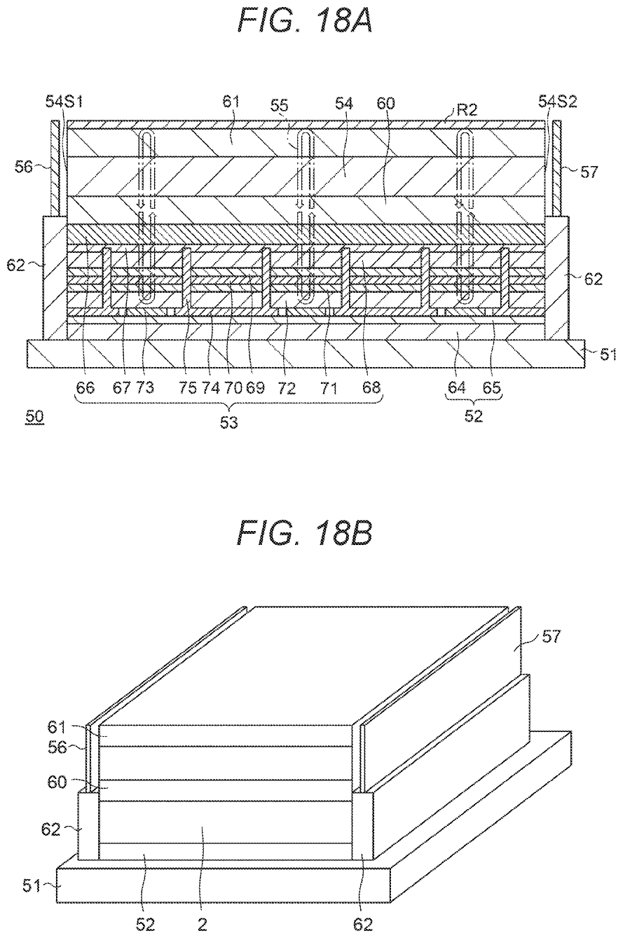

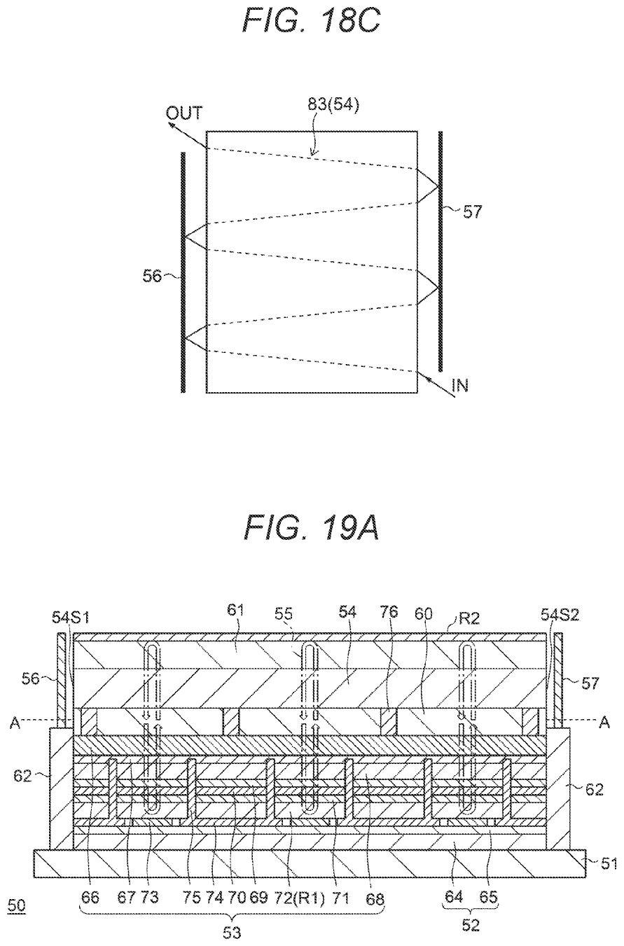

FIG. 18A is a cross-sectional view of a laser amplification element 50 according to the present disclosure, and FIG. 18B is a perspective view of the laser amplification element 50 according to the present disclosure. Furthermore, FIG. 18C is a plan view schematically illustrating an optical path of laser light in the laser amplification element 50.

A laser amplification element 50 according to FIGS. 18A to 18C includes an excitation light source 53 disposed on a support substrate 51 via a submount substrate 52 and a solid-state laser medium 54 disposed on the excitation light source 53, and is not provided with a saturable absorber 4. The solid-state laser medium 54 is, for example, Yb:YAG. As will be described later, the excitation light source 53 and the solid-state laser medium 54 form a first resonator 55, and the light of the first wavelength is resonated in the vertical direction (lamination direction) in FIG. 18A. More specifically, the first resonator 55 causes the light of the first wavelength to resonate between the first reflection layer R1 (p-DBR 72) in the excitation light source 53 and the second reflection layer R2 in the solid-state laser medium 54. While the solid-state laser medium 3 in the laser element 1 of FIG. 1 has the second reflection layer R2 on the end face facing the excitation light source 2 and the third reflection layer R3 on the end face facing the saturable absorber 4, the solid-state laser medium 54 of FIG. 18A does not need a reflection layer on the end face facing the excitation light source 53 and has the second reflection layer R2 on the opposite end face.

Furthermore, the laser amplification element 50 according to FIGS. 18A to 18C includes: a first reflection member 56 and a second reflection member 57 arranged along a first side surface 54S1 and a second side surface 54S2 of the solid-state laser medium 54 that face each other; and the solid-state laser medium 54 functioning as the amplification medium 83 that reciprocates the light of the second wavelength λ2 a plurality of times between the first reflection member 56 and the second reflection member 57.

Each of the first reflection member 56 and the second reflection member 57 may have a flat reflection mirror, or may have a reflection mirror having a convex shape in order to increase light density in the process of amplification and avoid optical damage to the material.

In FIG. 18A, the first reflection member 56 and the second reflection member 57 are disposed at a distance from the first side surface 54S1 and the second side surface 54S2 of the solid-state laser medium 54. However, a multilayer film formed by layering at least one of a semiconductor material, a metal material, or a dielectric material may be formed on each of the first side surface 54S1 and the second side surface 54S2, and the multilayer film may be used as a reflection mirror.

Moreover, the laser amplification element 50 according to FIGS. 18A to 18C includes a light input unit IN provided along the first side surface 54S1 and a light output unit OUT provided along the second side surface 54S2. The light input unit IN causes weak light (seed light) of the second wavelength λ2 to be incident on the first side surface 54S1. The light of the second wavelength λ2 reciprocates a plurality of times in the amplification medium 83 and is emitted from the light output unit OUT.

Furthermore, the laser amplification element 50 in FIGS. 18A to 18C may include a first heat exhaust member 60 and a second heat exhaust member 61. The first heat exhaust member 60 is disposed between the excitation light source 53 and the solid-state laser medium 54, and dissipates heat generated by at least one of the excitation light source 53 or the solid-state laser medium 54. The second heat exhaust member 61 is bonded to the end face of the solid-state laser medium 54 opposite to the end face facing the excitation light source 53, and dissipates heat generated in the solid-state laser medium 54.

Note that, in a case where thermal interference between the excitation light source 53 and the solid-state laser medium 54 is not large, at least one of the first heat exhaust member 60 or the second heat exhaust member 61 may be omitted.

The first heat exhaust member 60 and the second heat exhaust member 61 are materials having a thermal conductivity higher than the solid-state laser medium 54, and are, for example, sapphire or YAG. The first heat exhaust member 60 and the second heat exhaust member 61 are transparent materials that transmit the light of the first wavelength.

Furthermore, the laser amplification element 50 according to FIGS. 18A to 18C may include a cooling member 62. The cooling member 62 is bonded to each of the side surfaces of the excitation light source 53, the first heat exhaust member 60, and the solid-state laser medium 54, and dissipates heat transferred from at least one of the excitation light source 53 or the solid-state laser medium 54 to the first heat exhaust member 60. The cooling member 62 is, for example, a metal material having high thermal conductivity such as Cu. The cooling member 62 may be bonded to a package (not illustrated) or may dissipate heat from the cooling member 62 to the package.

The support substrate 51 in the laser amplification element 50 according to FIGS. 18A to 18C is, for example, a Cu substrate, and the submount substrate 52 is disposed thereon. The submount substrate 52 has, for example, a laminated structure of a SiC layer 64 and an AuSn layer 65, and a p-electrode 73 and an n-electrode 74 of the excitation light source 53 are electrically insulated and bonded to each other on the AuSn layer 65.

The excitation light source 53 is a laminated semiconductor layer in which an n-contact layer 67, an n-DBR 68, a cladding layer 69, an active layer 70, a cladding layer 71, and a p-DBR 72 are sequentially laminated on an n-GaAs substrate 66. A p-electrode 73 and an n-electrode 74 are alternately arranged on the p-DBR 72. The p-electrode 73 is electrically connected to the p-DBR 72, and the n-electrode 74 is electrically connected to the n-DBR 68 via a via 75.

The laser amplification element 50 according to the present disclosure includes the first resonator 55 similarly to FIG. 1. The first resonator 55 causes the light of the first wavelength to resonate between the first reflection layer R1 in the excitation light source 53 and the second reflection layer R2 in the solid-state laser medium 54. The first reflection layer R1 is the p-DBR 72, and the second reflection layer R2 is disposed on the upper surface of a second heat exhaust member 61, for example. The solid-state laser medium 54 is excited by the resonance operation of the light of the first wavelength by the first resonator 55. In FIG. 18A, the resonance operation of the first resonator 55 is schematically indicated by a thin line. The light to be amplified (seed light) of the second wavelength λ2 is made incident on the solid-state laser medium 54 in the excited state in the left direction from the right end in FIG. 18A. As a result, induced emission of the light to be amplified occurs, and the light to be amplified is laser amplified.

Furthermore, in a case where Yb:YAG is used as the amplification medium 83, when laser light having a wavelength of 1030 nm is used as seed light, the laser light is absorbed in an unexcited region in the amplification medium 83, resulting in a problem that sufficient amplification cannot be performed. Therefore, in a case where Yb:YAG is used as the amplification medium 83, seed light having a wavelength of 1050 nm that does not cause light absorption even in a non-excited state can be used. In this case, it is sufficient that light absorption does not occur even in the non-excited state, and hence the wavelength of the seed light is not limited to 1050 nm.

As described above, by providing the solid-state laser medium 54 inside the first resonator 55, as illustrated in FIGS. 17A to 17C, the two excitation light sources 53 required in a case where the solid-state laser medium 54 is excited from both end faces of the solid-state laser medium 54 are unnecessary, and the optical configuration can be greatly simplified and reduced in size.

Furthermore, since the size of the solid-state laser medium 54 in the laser amplification element 50 according to the present disclosure is not limited by the absorption length of the excitation light, the area of the solid-state laser medium 54 can be increased regardless of the absorption length of the excitation light. Increasing the area of the solid-state laser medium 54 enables further improvement in the amplification factor of the laser amplification element 50

Moreover, the laser amplification element 50 according to the present disclosure can integrally bond the excitation light source 53 including the laminated semiconductor layer and the solid-state laser medium 54, and can be manufactured by a general-purpose semiconductor process, thus facilitating size reduction and enabling a reduction in manufacturing cost.

Furthermore, the laser amplification element 50 according to the present disclosure bonds the first heat exhaust member 60 and the second heat exhaust member 61 to both surfaces of the solid-state laser medium 54, thus making it possible to inhibit the temperature rise of the solid-state laser medium 54 and to prevent thermal interference between the excitation light source 53 and the solid-state laser medium 54.

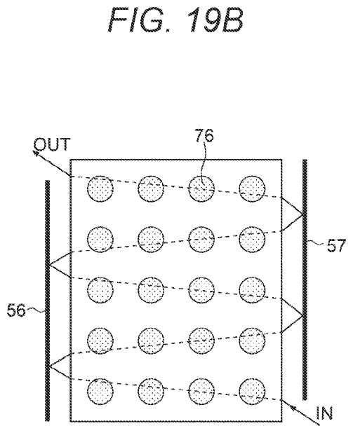

To efficiently exhaust the heat of the excitation light source 53 and the solid-state laser medium 54 to the first heat exhaust member 60, a plurality of via members 76 may be provided in the first heat exhaust member 60. FIG. 19A is a cross-sectional view of the laser amplification element 50 in which the heat exhaust performance of the first heat exhaust member 60 in FIG. 18A has been improved. The first heat exhaust member 60 in FIG. 19A includes a plurality of via members 76 that penetrate the first heat exhaust member 60 and are bonded to the excitation light source 53 and the solid-state laser medium 54. These via members 76 are filled with a material having a thermal conductivity higher than the base material of the first heat exhaust member 60.

FIG. 19B is a transverse cross-sectional view taken along line A-A in FIG. 19A. FIG. 19B illustrates an example in which the plurality of via members 76 is arranged at regular intervals in the two-dimensional direction, but the arrangement place, the diameter size, and the number of via members 76 are arbitrary. Since the thermal conductivity of the plurality of via members 76 is higher than the thermal conductivity of the solid-state laser medium 54, the heat transferred from the excitation light source 53 and the solid-state laser medium 54 to the via members 76 is exhausted to the cooling member 62 via the first heat exhaust member 60.

As described above, in the laser amplification element 50 illustrated in FIGS. 18A to 18C or FIGS. 19A to 19B, in the first resonator 55 including the first reflection layer R1 in the excitation light source 53 and the second reflection layer R2 in the solid-state laser medium 54, the light of the first wavelength is resonated in the lamination direction to bring the solid-state laser medium 54 into the excited state. Then, in this state, the light of the second wavelength λ2 is made horizontally incident from the end face of the solid-state laser medium 54, and is reflected many times between the two reflection mirrors provided along the two opposing end faces of the solid-state laser medium 54, so that the light of the second wavelength λ2 can be sufficiently amplified and emitted.

According to the laser amplification element 50 illustrated in FIGS. 18A to 18C or FIGS. 19A to 19B, the excitation light source 53 and the solid-state laser medium 54 have an integrated structure and can be formed using the semiconductor process technology, so that the solid-state laser medium 54 can be brought into the excited state while a small size is achieved. Furthermore, the light of the second wavelength λ2 to be optically amplified is incident in the horizontal direction from the end face of the solid-state laser medium 54, and is repeatedly reflected by the first reflection member 56 and the second reflection member 57 arranged along the two facing side surfaces 54S1, 54S2 of the solid-state laser medium 54 to amplify the light of the second wavelength λ2, so that the light of the second wavelength λ2 can be amplified with a sufficient amplification factor while a small size is achieved.

### Application Examples

The technology according to the present disclosure can be widely applied to a medical imaging system (hereinafter, also referred to as an electronic device), a ranging system such as a light detection and ranging (LiDAR) device, a light source for a laser processing device, and the like. The medical imaging system is a medical system using an imaging technology, and is, for example, an endoscope system or a microscope system.

### [Endoscope System]

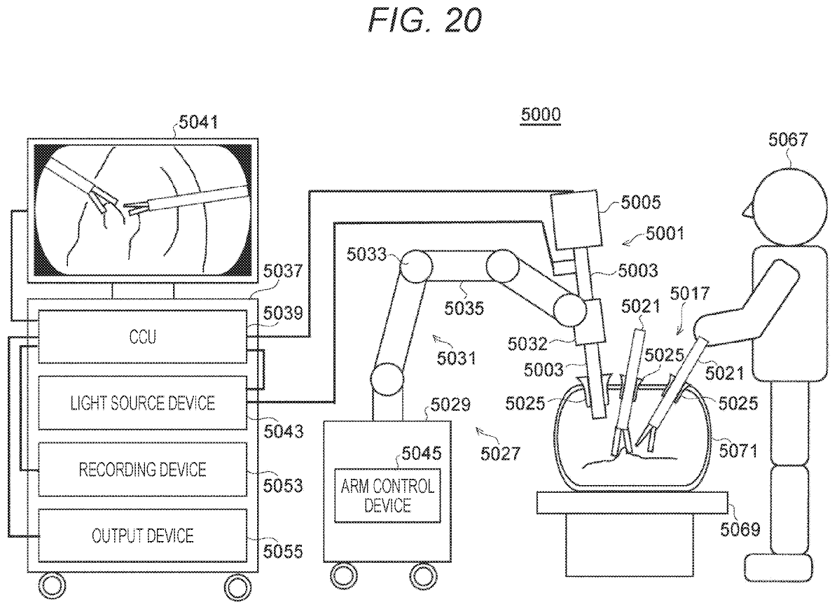

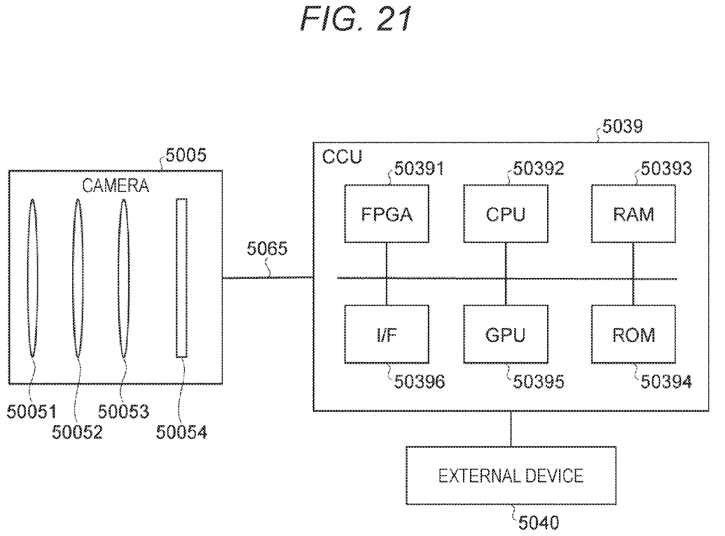

An example of an endoscope system will be described with reference to FIGS. 20 and 21. FIG. 20 is a diagram illustrating an example of a schematic configuration of an endoscope system 5000 to which the technology according to the present disclosure can be applied. FIG. 21 is a diagram illustrating an example of a configuration of an endoscope 5001 and a camera control unit (CCU) 5039. FIG. 20 illustrates a state in which an operator (e.g., doctor) 5067, who is a surgery participant, is performing surgery on a patient 5071 on a patient bed 5069 using the endoscope system 5000. As illustrated in FIG. 20, the endoscope system 5000 includes the endoscope 5001 that is a medical imaging device, the CCU 5039, a light source device 5043, a recording device 5053, an output device 5055, and a support device 5027 that supports the endoscope 5001.

In endoscopic surgery, insertion assisting tools called trocars 5025 are punctured into the patient 5071. Then, a scope 5003 connected to the endoscope 5001 and surgical tools 5021 are inserted into a body of the patient 5071 through the trocars 5025. The surgical tools 5021 include: an energy device such as an electric scalpel; and forceps, for example.

A surgical image that is a medical image in which the inside of the body of the patient 5071 is captured by the endoscope 5001 is displayed on a display device 5041. The operator 5067 performs a procedure on a surgical target using the surgical tools 5021 while viewing the surgical image displayed on the display device 5041. The medical image is not limited to the surgical image, and may be a diagnostic image captured during diagnosis.

### [Endoscope]

The endoscope 5001 is an imaging unit for capturing the inside of the body of the patient 5071, and is, for example, as illustrated in FIG. 21, a camera 5005 that includes a condensing optical system 50051 for condensing incident light, a zooming optical system 50052 capable of optical zooming by changing the focal length of the imaging unit, a focusing optical system 50053 capable of focus adjustment by changing the focal length of the imaging unit, and a light receiving sensor 50054. The endoscope 5001 condenses the light through the connected scope 5003 on the light receiving sensor 50054 to generate a pixel signal, and outputs the pixel signal through a transmission system to the CCU 5039. The scope 5003 is an insertion part that includes an objective lens at a distal end and guides the light from the connected light source device 5043 into the body of the patient 5071. The scope 5003 is, for example, a rigid scope for a rigid endoscope and a flexible scope for a flexible endoscope. The scope 5003 may be a direct viewing scope or an oblique viewing scope. The pixel signal only needs to be a signal based on a signal output from a pixel, and is, for example, a raw signal or an image signal. The transmission system connecting the endoscope 5001 to the CCU 5039 may include a memory, and the memory may store parameters related to the endoscope 5001 and the CCU 5039. The memory may be disposed at a connection portion of the transmission system or on a cable. For example, the memory of the transmission system may store the parameters before shipment of the endoscope 5001 or the parameters changed when current is applied, and an operation of the endoscope may be changed based on the parameters read from the memory. A set of the camera and the transmission system may be referred to as an endoscope. The light receiving sensor 50054 is a sensor for converting the received light into the pixel signal, and is, for example, a complementary metal-oxide-semiconductor (CMOS) imaging sensor. The light receiving sensor 50054 is preferably an imaging sensor having a Bayer array capable of color imaging. The light receiving sensor 50054 is also preferably an imaging sensor having a number of pixels corresponding to a resolution of, for example, 4K (3840 horizontal pixels×2160 vertical pixels), 8K (7680 horizontal pixels×4320 vertical pixels), or square 4K (3840 or more horizontal pixels×3840 or more vertical pixels). The light receiving sensor 50054 may be one sensor chip, or a plurality of sensor chips. For example, a prism may be provided to separate the incident light into predetermined wavelength bands, and the wavelength bands may be imaged by different light receiving sensors. A plurality of light receiving sensors may be provided for stereoscopic viewing. The light receiving sensor 50054 may be a sensor having a chip structure including an arithmetic processing circuit for image processing, or may be a sensor for time of flight (ToF). The transmission system is, for example, an optical fiber cable system or a wireless transmission system. The wireless transmission only needs to be capable of transmitting the pixel signal generated by the endoscope 5001, and, for example, the endoscope 5001 may be wirelessly connected to the CCU 5039, or the endoscope 5001 may be connected to the CCU 5039 via a base station in an operating room. At this time, the endoscope 5001 may transmit not only the pixel signal, but also simultaneously information (for example, a processing priority of the pixel signal and/or a synchronization signal) related to the pixel signal. In the endoscope, the scope may be integrated with the camera, and the light receiving sensor may be provided at the distal end of the scope.

### [CCU (Camera Control Unit)]

The CCU 5039 is a control device that integrally controls the connected endoscope 5001 and light source device 5043, and is, for example, an information processing device including an FPGA 50391, a CPU 50392, a RAM 50393, a ROM 50394, a GPU 50395, and an I/F 50396 as illustrated in FIG. 21. The CCU 5039 may control the display device 5041, the recording device 5053, and the output device 5055 connected to the CCU 5039 in an integrated manner. The CCU 5039 controls, for example, irradiation timing, irradiation intensity, and a type of an irradiation light source of the light source device 5043. The CCU 5039 also performs image processing, such as development processing (for example, demosaic processing) and correction processing, on the pixel signal output from the endoscope 5001, and outputs the processed image signal (for example, an image) to an external device such as the display device 5041. The CCU 5039 also transmits a control signal to the endoscope 5001 to control driving of the endoscope 5001. The control signal is information on an imaging condition such as a magnification or the focal length of the imaging section. The CCU 5039 may have a function to down-convert the image, and may be configured to be capable of simultaneously outputting a higher-resolution (for example, 4K) image to the display device 5041 and a lower-resolution (for example, high-definition (HD)) image to the recording device 5053.

The CCU 5039 may be connected to external equipment (such as a recording device, a display device, an output device, and a support device) via an IP converter for converting the signal into a predetermined communication protocol (such as the Internet Protocol (IP)). The connection between the IP converter and the external equipment may be established using a wired network, or a part or the whole of the network may be established using a wireless network. For example, the IP converter on the CCU 5039 side may have a wireless communication function, and may transmit the received image to an IP switcher or an output side IP converter via a wireless communication network, such as the fifth-generation mobile communication system (5G) or the sixth-generation mobile communication system (6G).

### [Light Source Device]

The light source device 5043 is a device capable of emitting the light having predetermined wavelength bands, and includes, for example, a plurality of light sources and a light source optical system for guiding the light of the light sources. The light sources are, for example, xenon lamps, light-emitting diode (LED) light sources, or laser diode (LD) light sources. The light source device 5043 includes, for example, the LED light sources corresponding to three respective primary colors of red (R), green (G), and blue (B), and controls output intensity and output timing of each of the light sources to emit white light. The light source device 5043 may include a light source capable of emitting special light used for special light observation, in addition to the light sources for emitting normal light for normal light observation. The special light is light having a predetermined wavelength band different from that of the normal light being light for the normal light observation, and is, for example, near-infrared light (light having a wavelength of 760 nm or longer), infrared light, blue light, or ultraviolet light. The normal light is, for example, the white light or green light. In narrow band imaging that is a kind of special light observation, blue light and green light are alternately emitted, and thus the narrow band imaging can image a predetermined tissue such as a blood vessel in a mucosal surface at high contrast using wavelength dependence of light absorption in the tissue of the body. In fluorescence observation that is a kind of special light observation, excitation light is emitted for exciting an agent injected into the tissue of the body, and fluorescence emitted by the tissue of the body or the agent as a label is received to obtain a fluorescent image, and thus the fluorescence observation can facilitate the operator to view, for example, the tissue of the body that is difficult to be viewed by the operator with the normal light. For example, in fluorescence observation using the infrared light, the infrared light having an excitation wavelength band is emitted to an agent, such as indocyanine green (ICG), injected into the tissue of the body, and the fluorescence light from the agent is received, whereby the fluorescence observation can facilitate viewing of a structure and an affected part of the tissue of the body. In the fluorescence observation, an agent (such as 5-aminolevulinic acid (5-ALA)) may be used that emits fluorescence in a red wavelength band by being excited by the special light in a blue wavelength band. The type of the irradiation light of the light source device 5043 is set by control of the CCU 5039. The CCU 5039 may have a mode of controlling the light source device 5043 and the endoscope 5001 to alternately perform the normal light observation and the special light observation. At this time, information based on a pixel signal obtained by the special light observation is preferably superimposed on a pixel signal obtained by the normal light observation. The special light observation may be an infrared light observation to observe a site inside the surface of an organ and a multi-spectrum observation utilizing hyperspectral spectroscopy. A photodynamic therapy may be incorporated.

### [Recording Device]

The recording device 5053 is a device for recording the pixel signal (for example, an image) acquired from the CCU 5039, and is, for example, a recorder. The recording device 5053 records an image acquired from the CCU 5039 in a hard disk drive (HDD), a Super Density Disc (SDD), and/or an optical disc. The recording device 5053 may be connected to a network in a hospital to be accessible from equipment outside the operating room. The recording device 5053 may have a down-convert function or an up-convert function.

### [Display Device]

The display device 5041 is a device capable of displaying the image, and is, for example, a display monitor. The display device 5041 displays a display image based on the pixel signal acquired from the CCU 5039. The display device 5041 may include a camera and a microphone to function as an input device that allows instruction input through gaze recognition, voice recognition, and gesture.

### [Output Device]

The output device 5055 is a device for outputting the information acquired from the CCU 5039, and is, for example, a printer. The output device 5055 prints, for example, a print image based on the pixel signal acquired from the CCU 5039 on a sheet of paper.

### [Support Device]

The support device 5027 is an articulated arm including a base 5029 including an arm control device 5045, an arm 5031 extending from the base 5029, and a holding part 5032 mounted at a distal end of the arm 5031. The arm control device 5045 includes a processor such as a CPU, and operates according to a predetermined computer program to control driving of the arm 5031. The support device 5027 uses the arm control device 5045 to control parameters including, for example, lengths of links 5035 constituting the arm 5031 and rotation angles and torque of joints 5033 so as to control, for example, the position and attitude of the endoscope 5001 held by the holding part 5032. This control can change the position or attitude of the endoscope 5001 to a desired position or attitude, makes it possible to insert the scope 5003 into the patient 5071, and can change the observed area in the body. The support device 5027 functions as an endoscope support arm for supporting the endoscope 5001 during the operation. Thus, the support device 5027 can play a role of a scopist who is an assistant holding the endoscope 5001. The support device 5027 may be a device for holding a microscope device 5301 to be described later, and can be called a medical support arm. The support device 5027 may be controlled using an autonomous control method by the arm control device 5045, or may be controlled using a control method in which the arm control device 5045 performs the control based on input of a user. The control method may be, for example, a master-slave method in which the support device 5027 serving as a slave device (replica device) that is a patient cart is controlled based on a movement of a master device (primary device) that is an operator console at a hand of the user. The support device 5027 may be remotely controllable from outside the operating room.

The example of the endoscope system 5000 to which the technology according to the present disclosure is applicable has been described above. For example, the technology according to the present disclosure may be applied to a microscope system.

### [Microscope System]

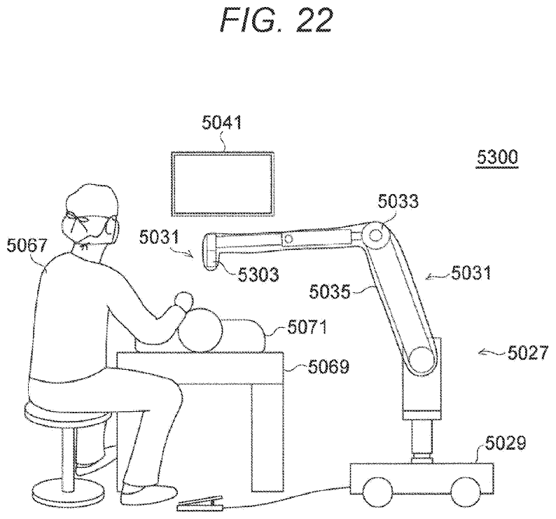

FIG. 22 is a diagram illustrating an example of a schematic configuration of a microscopic surgery system to which the technology according to the present disclosure is applicable. In the following description, the same components as those of the endoscope system 5000 will be denoted by the same reference numerals, and the description thereof will not be repeated.

FIG. 22 schematically illustrates a state in which the operator 5067 is performing surgery on the patient 5071 on the patient bed 5069 using a microscopic surgery system 5300. Note that, for the sake of simplicity, FIG. 22 does not illustrate a cart 5037 among the components of the microscopic surgery system 5300, and illustrates the microscope device 5301 instead of the endoscope 5001 in a simplified manner. The microscope device 5301 may refer to a microscope 5303 provided at the distal end of the links 5035, or may refer to the overall configuration including the microscope 5303 and the support device 5027.

As illustrated in FIG. 22, during the operation, the microscopic surgery system 5300 is used to display an image of a surgical site captured by the microscope device 5301 in a magnified manner on the display device 5041 installed in the operating room. The display device 5041 is installed in a position facing the operator 5067, and the operator 5067 performs various procedures, such as excision of an affected part, on the surgical site while observing the state of the surgical site using the image displayed on the display device 5041. The microscopic surgery system is used in, for example, ophthalmic operation and neurosurgical operation.

The respective examples of the endoscope system 5000 and the microscopic surgery system 5300 to which the technology according to the present disclosure is applicable have been described above. Systems to which the technology according to the present disclosure is applicable are not limited to such examples. For example, the support device 5027 can support, at the distal end thereof, another observation device or another surgical tool instead of the endoscope 5001 or the microscope 5303. Examples of the other applicable observation device include forceps, tweezers, a pneumoperitoneum tube for pneumoperitoneum, and an energy treatment tool for incising a tissue or sealing a blood vessel by cauterization. By using the support device to support the observation device or the surgical tool described above, the position thereof can be more stably fixed and the load of the medical staff can be lower than in a case where the medical staff manually supports the observation device or the surgical tool. The technology according to the present disclosure may be applied to a support device for supporting such a component other than the microscope.

The technology according to the present disclosure is suitably applicable to the surgical tools 5021 among the components described above. Specifically, by irradiating the affected site of the patient with a short-pulse laser pulse from the laser element 1 according to the present embodiment, it is possible to more safely and reliably treat the affected site without damaging the periphery of the affected site.

Note that the present technology can have the following configurations.

(1) A laser element including:
a laminated semiconductor layer including a first reflection layer with respect to a first wavelength and an active layer that performs surface emission at the first wavelength;
a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface on a side opposite to the first surface;
a fourth reflection layer with respect to the second wavelength, the forth reflection layer being disposed on the second surface or disposed on a rear side of the optical axis with respect to the second surface;
a first resonator that causes light of the first wavelength to resonate between the first reflection layer and the third reflection layer;
a second resonator that causes light of the second wavelength to resonate between the second reflection layer and the fourth reflection layer; and
a heat exhaust unit that is disposed between the laminated semiconductor layer and the laser medium, and exhausts heat generated in at least one of the laminated semiconductor layer or the laser medium,
in which the optical axis of the laminated semiconductor layer and an optical axis of the laser medium are coaxially arranged.

(2) The laser element according to (1), in which the heat exhaust unit includes a first member disposed between the laminated semiconductor layer and the laser medium and having a thermal conductivity higher than the laser medium.

(3) The laser element according to (2), further including a metal layer disposed on a part or all of a surface of the first member on a side facing the laser medium and having a thermal conductivity higher than the laminated semiconductor layer and the laser medium.

(4) The laser element according to (2) or (3), further including a second member that is bonded to a side surface of the laminated semiconductor layer, a side surface of the first member, and a side surface of the laser medium and dissipates heat transmitted to the first member.

(5) The laser element according to (4), further including:
a substrate that supports the laminated semiconductor layer; and
a bonding wire connected to a pad on the substrate and an electrode of the laminated semiconductor layer,
in which the second member is disposed to cover the side surface of the laminated semiconductor layer, the side surface of the laser medium, and the bonding wire.

(6) The laser element according to (4) or (5), in which
the first member contains at least one of sapphire or diamond, and
the second member includes a metal material.

(7) The laser element according to any one of (2) to (6), further including a protective layer that is disposed on a surface of the first member on a side facing the laminated semiconductor layer, transmits light of the first wavelength, and reflects light of the second wavelength.

(8) The laser element according to any one of (1) to (7), in which the first member includes a first region that transmits the light of the first wavelength, and a second region that is disposed around the first region and has a higher thermal conductivity than the laser medium.

(9) The laser element according to (8), in which the second region is formed by an insulating material or a metal material.

(10) The laser element according to (8) or (9), in which
the second region is disposed to surround the first region, and
an outer peripheral surface of the second region or a corner portion of the outer peripheral surface is located at an equal distance from a center position of the first region.

(11) The laser element according to any one of (1) to (10), including a plurality of the first resonators and a plurality of the second resonators in a plane direction of the laminated semiconductor layer, the heat exhaust unit, and the laser medium.

(12) The laser element according to (1), in which the heat exhaust unit has an air gap disposed between the laminated semiconductor layer and the laser medium.

(13) The laser element according to any one of (1) to (12), further including a first optical element that is disposed between the second reflection layer and the fourth reflection layer, and increases a beam diameter of the light of the second wavelength.

(14) The laser element according to any one of (1) to (13), in which the first resonator includes a second optical element that condenses the light of the first wavelength in an optical axis direction.

(15) The laser element according to any one of (1) to (14), further including a saturable absorber including a fourth reflection layer on a third surface on a side opposite to the laser medium,
in which the optical axis of the laminated semiconductor layer, the optical axis of the laser medium, and the optical axis of the saturable absorber are coaxially arranged.

(16) The laser element according to (15), in which the laminated semiconductor layer, the laser medium, and the saturable absorber are integrally bonded.

(17) The laser element according to (15) or (16), further including a polarization control element that is disposed between the laser medium and the saturable absorber or on an optical axis rear side of the saturable absorber, and controls a polarization state of the light of the second wavelength.

(18) The laser element according to claim 1, in which the fourth reflection layer is an output coupling mirror in the second resonator.

(19) The laser element according to claim 1, in which
the laminated semiconductor layer includes a fifth reflection layer with respect to the first wavelength disposed on a side closer to the laser medium than the first reflection layer, and
the fifth reflection layer transmits a part of the light of the first wavelength.
(20) An electronic device including:
a laser element; and
a control unit that performs control to emit light from the laser element,
in which
the laser element includes
a laminated semiconductor layer including a first reflection layer with respect to a first wavelength and an active layer that performs surface emission at the first wavelength,
a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface on a side opposite to the first surface,
a fourth reflection layer with respect to the second wavelength, the forth reflection layer being disposed on the second surface or disposed on a rear side of the optical axis with respect to the second surface,
a first resonator that causes light of the first wavelength to resonate between the first reflection layer and the third reflection layer,
a second resonator that causes light of the second wavelength to resonate between the second reflection layer and the fourth reflection layer, and
a heat exhaust unit that is disposed between the laminated semiconductor layer and the laser medium, and exhausts heat generated in at least one of the laminated semiconductor layer or the laser medium, and
in which the optical axis of the laminated semiconductor layer and an optical axis of the laser medium are coaxially arranged.

(21) A laser amplification element including:
a laminated semiconductor layer including a first reflection layer with respect to a first wavelength and an active layer that performs surface emission at the first wavelength;
a laser medium disposed on a rear side of an optical axis of the laminated semiconductor layer and including a second reflection layer with respect to the first wavelength on a second surface opposite to a first surface facing the laminated semiconductor layer;
a first reflection member and a second reflection member arranged along a first side surface and a second side surface facing each other of the laser medium;
a light input unit that is provided along the first side surface and inputs light of a second wavelength;
a light output unit that is provided along the second side surface and amplifies and outputs light of the second wavelength; and
a first resonator that causes light of the first wavelength to resonate between the first reflection layer and the second reflection layer,
in which
the laser medium is an amplification medium that causes light of the second wavelength to reciprocate a plurality of times between the first reflection member and the second reflection member, and
the optical axis of the laminated semiconductor layer and an optical axis of the laser medium are coaxially arranged.

(22) The laser amplification element according to (21), in which in a state where the laser medium is excited by resonance operation of the light of the first wavelength performed by the first resonator, the light of the second wavelength is incident from the light input unit, the light of the second wavelength is reciprocated a plurality of times in the amplification medium, and then the light of the second wavelength is amplified and output from the light output unit.

(23) The laser amplification element according to (21) or (22), further including a first heat exhaust member that is disposed between the laminated semiconductor layer and the laser medium, and exhausts heat generated in at least one of the laminated semiconductor layer or the laser medium,
in which the optical axis of the laminated semiconductor layer, an optical axis of the first heat exhaust member, and the optical axis of the laser medium are coaxially arranged.

(24) The laser amplification element according to (23), in which thermal conductivity of the first heat exhaust member is higher than thermal conductivity of the laser medium.

(25) The laser amplification element according to (23) or (24), further including a second heat exhaust member that is bonded to an end face of the laser medium on a side opposite to an end face facing the laminated semiconductor layer and exhausts heat generated by the laser medium.

(26) The laser amplification element according to (25), in which thermal conductivity of the second heat exhaust member is higher than thermal conductivity of the laser medium.

(27) The laser amplification element according to any one of (23) to (26), further including a cooling member that is bonded to the laminated semiconductor layer, the first heat exhaust member, and a side surface of the laser medium and dissipates heat transferred from at least one of the laminated semiconductor layer or the laser medium to the first heat exhaust member.

(28) The laser amplification element according to any one of (23) to (27), in which
the first heat exhaust member includes a plurality of via members that penetrate the first heat exhaust member and are bonded to the laminated semiconductor and the laser medium, and
thermal conductivity of the plurality of via members is higher than the thermal conductivity of the first heat exhaust member.

(29) The laser amplification element according to any one of (21) to (28), in which the first reflection member and the second reflection member are convex mirror members that reflect incident light so as not to be condensed.

(30) The laser amplification element according to any one of (21) to (29), in which the first reflection member and the second reflection member are multilayer films that are disposed on the first side surface and the second side surface and formed by layering at least one of a semiconductor material, a metal material, or a dielectric material.

Aspects of the present disclosure are not limited to the individual embodiments described above, but include various modifications that can be conceived by those skilled in the art, and the effects of the present disclosure are not limited to the contents described above. That is, various additions, modifications, and partial deletions are possible without departing from the conceptual idea and spirit of the present disclosure derived from the matters defined in the claims and equivalents thereof.

### REFERENCE SIGNS LIST

1 Laser element
2 Laminated semiconductor layer (excitation light source)
3 Solid-state laser medium
4 Saturable absorber
5 n-GaAs substrate
6 Cladding layer
7 Active layer
8 Cladding layer
9 Optical element
11 First resonator
12 Second resonator
13 Heat exhaust unit
13a First region
13b Second region
14 Cooling member (second member)
16 Bonding wire
17 Heat exhaust member (first member)
17 Heat exhaust member
18 Metal layer
19 First protective layer
20 Second protective layer
21 Resist film
22 Photomask
23 Recess
24 Dielectric multilayer film
25 Alignment mark
26 Camera
27 First transparent medium
28 Second transparent medium
29 Transparent member
31 Contact layer
32 Oxide layer (e.g., Al2O3 layer)
33 Contact layer
34 Insulating film
35 Conductive material
41 Optical element
42 Convex mirror
43 Light control member
44 Laser array
45 Transparent substrate
50 Laser amplification element
51 Support substrate
52 Submount substrate
53 Excitation light source
54 Solid-state laser medium
54S1 First side surface
54S1 Side surface
54S2 Second side surface
55 First resonator
56 First reflection member
57 Second reflection member
58 Second resonator
60 First heat exhaust member
61 Second heat exhaust member
62 Cooling member
64 SiC layer
65 AuSn layer
66 n-GaAs substrate
67 Contact layer
69 Cladding layer
70 Active layer
71 Cladding layer
73 p-electrode
74 n-electrode
75 Via
76 Via member
81 Excitation light source
82 Excitation light source
83 Amplification medium
84 Polarizer
85 λ/4 plate
86 Laser array
87 Waveguide
91 Submount substrate
92 Support substrate

1. A laser element comprising:
a laminated semiconductor layer including a first reflection layer with respect to a first wavelength and an active layer that performs surface emission at the first wavelength;
a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface on a side opposite to the first surface;
a fourth reflection layer with respect to the second wavelength, the forth reflection layer being disposed on the second surface or disposed on a rear side of the optical axis with respect to the second surface;
a first resonator that causes light of the first wavelength to resonate between the first reflection layer and the third reflection layer;
a second resonator that causes light of the second wavelength to resonate between the second reflection layer and the fourth reflection layer; and
a heat exhaust unit that is disposed between the laminated semiconductor layer and the laser medium, and exhausts heat generated in at least one of the laminated semiconductor layer or the laser medium,
wherein the optical axis of the laminated semiconductor layer and an optical axis of the laser medium are coaxially arranged.

2. The laser element according to claim 1, wherein the heat exhaust unit includes a first member disposed between the laminated semiconductor layer and the laser medium and having a thermal conductivity higher than the laser medium.

3. The laser element according to claim 2, further comprising a metal layer disposed on a part or all of a surface of the first member on a side facing the laser medium and having a thermal conductivity higher than the laminated semiconductor layer and the laser medium.

4. The laser element according to claim 2, further comprising a second member that is bonded to a side surface of the laminated semiconductor layer, a side surface of the first member, and a side surface of the laser medium and dissipates heat transmitted to the first member.

5. The laser element according to claim 4, further comprising:
a substrate that supports the laminated semiconductor layer; and
a bonding wire connected to a pad on the substrate and an electrode of the laminated semiconductor layer,
wherein the second member is disposed to cover the side surface of the laminated semiconductor layer, the side surface of the laser medium, and the bonding wire.

6. The laser element according to claim 4, wherein
the first member contains at least one of sapphire or diamond, and
the second member includes a metal material.

7. The laser element according to claim 2, further comprising a protective layer that is disposed on a surface of the first member on a side facing the laminated semiconductor layer, transmits light of the first wavelength, and reflects light of the second wavelength.

8. The laser element according to claim 2, wherein the first member includes a first region that transmits the light of the first wavelength, and a second region that is disposed around the first region and has a higher thermal conductivity than the laser medium.

9. The laser element according to claim 8, wherein the second region is an insulating material or a metal material.

10. The laser element according to claim 8, wherein
the second region is disposed to surround the first region, and
an outer peripheral surface of the second region or a corner portion of the outer peripheral surface is located at an equal distance from a center position of the first region.

11. The laser element according to claim 1, further comprising a plurality of the first resonators and a plurality of the second resonators in a plane direction of the laminated semiconductor layer, the heat exhaust unit, and the laser medium.

12. The laser element according to claim 1, wherein the heat exhaust unit has an air gap disposed between the laminated semiconductor layer and the laser medium.

13. The laser element according to claim 1, further comprising a first optical element that is disposed between the second reflection layer and the fourth reflection layer, and increases a beam diameter of the light of the second wavelength.

14. The laser element according to claim 1, wherein the first resonator includes a second optical element that condenses the light of the first wavelength in an optical axis direction.

15. The laser element according to claim 1, further comprising a saturable absorber that includes a fourth reflection layer on a third surface on a side opposite to the laser medium,
wherein the optical axis of the laminated semiconductor layer, the optical axis of the laser medium, and the optical axis of the saturable absorber are coaxially arranged.

16. The laser element according to claim 15, wherein the laminated semiconductor layer, the laser medium, and the saturable absorber are integrally bonded.

17. The laser element according to claim 15, further comprising a polarization control element that is disposed between the laser medium and the saturable absorber or on a rear side of an optical axis with respect to the saturable absorber, and controls a polarization state of the light of the second wavelength.

18. The laser element according to claim 1, wherein the fourth reflection layer is an output coupling mirror in the second resonator.

19. The laser element according to claim 1, wherein
the laminated semiconductor layer includes a fifth reflection layer with respect to the first wavelength disposed on a side closer to the laser medium than the first reflection layer, and
the fifth reflection layer transmits a part of the light of the first wavelength.

20. An electronic device comprising:
a laser element; and
a control unit that performs control to emit light from the laser element,
wherein
the laser element includes
a laminated semiconductor layer including a first reflection layer with respect to a first wavelength and an active layer that performs surface emission at the first wavelength,
a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface on a side opposite to the first surface,
a fourth reflection layer with respect to the second wavelength, the forth reflection layer being disposed on the second surface or disposed on a rear side of the optical axis with respect to the second surface,
a first resonator that causes light of the first wavelength to resonate between the first reflection layer and the third reflection layer,
a second resonator that causes light of the second wavelength to resonate between the second reflection layer and the fourth reflection layer, and
a heat exhaust unit that is disposed between the laminated semiconductor layer and the laser medium, and exhausts heat generated in at least one of the laminated semiconductor layer or the laser medium, and
the optical axis of the laminated semiconductor layer and an optical axis of the laser medium are coaxially arranged.
